(19) United States
(12) Patent Application Publication
(10) Pub. No.: US 2007/0202797 A1
(43) Pub. Date: Aug. 30, 2007

(54) Solar cell, photoelectric conversion device and clean unit

(76) Inventor: Akira Ishibashi, Saporo-shi (JP)

Correspondence Address: MOORE & VAN ALLEN PLLC, P.O. BOX 13706, Research Triangle Park, NC, 27709, US

(21) Appl. No.: 11/708,855

(22) Filed: Feb. 21, 2007

Related U.S. Application Data
(63) Continuation of application No. PCT/JP05/17003, filed on Sep. 8, 2005.

(30) Foreign Application Priority Data
Sep. 9, 2004 (JP) 2004-262040
Dec. 24, 2004 (JP) 2004-375089

(51) Int. Cl. F24F 7/007

(52) U.S. Cl. 454/230

(57) ABSTRACT

In a clean unit in which an active dust filter is used to keep a work chamber as a clean environment, the cleanliness of the work chamber depends upon 1/γ where γ is the dust collection efficiency of the dust filter. A solar cell is formed from an anode and cathode formed spiral with a semiconductor layer being laid between them to have the general form of a plate. The solar cell has, for example, a circular, a triangular or hexagonal form.

### CROSS REFERENCE TO RELATED APPLICATIONS

The present application is a continuation of International Application No. PCT/JP2005/017003 filed on Sep. 8, 2005, and further the present application claims priority to Japan Patent Application No. P2004-262040 filed in the Japan Patent Office on Sep. 9, 2004, and Japan Patent Application No. P2004-375089 filed in the Japan Patent Office on Dec. 24, 2004.

### BACKGROUND

The present invention generally relates to integration of a bottom-up system and top-down system, and more particularly to a solar cell, photoelectric conversion device and clean unit.

The functional devices such as semiconductor integrated circuits have been produced in the past by a microfabrication-based top-down approach. Especially in the field of semiconductors, the giant semiconductor electronics industries based on the top-down approach have been established via the transistor invented by Bardeen et al. and the semiconductor integrated circuit invented by Noyce et al.

However, some limits have been found in various respects of this top-down approach. To overcome such limits, the bottom-up approach by self-organization or the like has recently been attracting attention and studied actively.

Also, there have been reported many solar cells of a type in which sunlight is incident perpendicularly upon the p-n junction surface (cf. the article by D. J. Friedman, F. J. Geisz, S. R. Kurtz and J. M. Olson, July 1998, NREL/CP-520-23874).

If the above-mentioned top-down and bottom-up systems can be integrated together, it will be possible to create a novel functional device by making the most of their advantages. As far as the Inventors of the present invention know, however, there has not yet been proposed in detail any effective technique for integration of top-down and bottom-up systems.

It is therefore desirable to provide an improved and novel solar cell and photoelectric conversion device.

It is also desirable to provide a clean unit system capable of carrying out processes correspondingly to a total series of on-target process flows, easily, with a high flexibility, at a lower cost and without having to use any large clean chamber requiring a large capital investment and on which a large fixed asset tax is imposed, and which is suitable for use to produce various types of functional devices, and a clean unit suitable for use in the clean unit system.

### SUMMARY

According a first aspect of the present invention, there is provided a solar cell including an anode and cathode formed spiral with a semiconductor layer laid between them to have the general form of a plate.

In the above solar cell, the semiconductor layer is capable of photoelectric conversion and may basically be in any form unless it is inconvenient to shape the anode and cathode in a spiral form. Typically, however, the semiconductor layer is an inorganic or organic semiconductor layer such as an amorphous silicon layer. The solar cell may be in any form, but it is typically formed circular, triangular or hexagonal. The anode and cathode are typically in the form of a strip or ribbon.

Also, according to a second aspect of the present invention, there is provided a photoelectric conversion device including a photoelectric conversion layer formed spiral or concentric to have the general form of a plate and upon which light is incident from a direction intersecting the plate, wherein the incident light that can be photoelectrically converted by the photoelectric conversion layer varies in wavelength stepwise and/or continuously in the direction of plate thickness.

Typically, first and second electrodes are formed spiral or concentric with a photoelectric conversion layer laid between them. Also, typically, at least one of the first and second electrodes, normally, at least the anode, is formed from a plurality of electrodes provided separately from each other in the direction of plate thickness. Also, typically, incident light that can be photoelectrically converted by the photoelectric conversion layer is stepwise larger in wavelength from the light-incident surface of the plate in the direction of plate thickness and at least one of the first and second electrodes is formed from a plurality of electrodes provided in positions corresponding to the steps of wavelength increase separately from each other in the direction of plate thickness. Typically, the photoelectric conversion layer is a p-n junction of a p-type semiconductor film and n-type semiconductor film. The p- and n-type semiconductor films may be of either an inorganic or organic semiconductor. Typically, they are formed from an inorganic or organic semiconductor whose composition is graded in the direction of plate thickness. Typically, the bandgap between the p- and n-type semiconductors decreases stepwise and/or continuously from the light-incident surface of the plate in the plate-thickness. The thickness of the first and second electrodes is selected as appropriate but it is typically selected within a range over 0.2 nm and under 100 nm. Also, the thickness of the photoelectric conversion layer is also selected as appropriate but it is typically selected within a range over 10 nm and under 100 nm. The photoelectric conversion layer may be formed from a dye-carrying semiconductor photoelectrode, electrolyte layer being in contact with the semiconductor photoelectrode and a counter-electrode being in contact with the electrolyte layer similarly to the well-known dye sensitizing wet solar cell. The electrolyte layer should preferably be a solid electrolyte layer. The solid electrolyte layer may be formed by printing, coating or the like. The semiconductor photoelectrode should typically be formed from a metal oxide (anatase-type titanium oxide, for example). Typically, the dye carried by the semiconductor photoelectrode is varied in type direction from the light-incident surface of the plate in the direction of plate thickness to stepwise increase the wavelength of the light absorbed by the dye. More specifically, the dye carried by the semiconductor photoelectrode is varied stepwise from a dye which absorbs light of a short wavelength to a dye which absorbs light of a long wavelength in the direction of plate thickness from the light-incident surface of the plate. The photoelectric conversion device may be in any form, but it is typically circular, triangular or hexagonal.

The above various elements can be produced with a high yield using only a novel clean unit or clean unit system according to the present invention which will be described below. Namely, they can be produced without using any conventional large-scale clean chamber requiring a large capital investment.

Also, according to a third aspect of the present invention, there is provided a clean unit including:

a work chamber that can be kept as a clean environment; and

connectors provided at at least the back, top and bottom of the work chamber and at at least one of opposite lateral sides of the work chamber, respectively.

Where the connectors of the work chamber are to be provided, at the back, top or bottom and at one of two lateral sides is appropriately selected depending upon how the clean units are to be disposed two- or three-dimensionally. For example, in case the clean units are disposed in a horizontal plane, the connectors should preferably be provided at the back and both lateral sides of the work chamber to increase the freedom of connection for an improved flexibility of a clean unit system. In this case, a total of three clean units can be connected to the back and both lateral sides of one clean unit. Also, in case the clean units are disposed in a vertical plane, the connectors should preferably be provided at the top or bottom and both lateral sides, respectively, of the work chamber to increase the freedom of connection for an improved flexibility of a clean unit system. In this case, a total of three clean units can be connected to the top or bottom and both lateral sides of one clean unit. Generally, the connector has an opening formed in the wall of the work chamber and a shield plate provided to open and close the opening. The shield plate may basically be any one as long as it can open and close the opening but it is typically a sliding door or hinged door. The shield plate may be adapted for manual operation or for automatic operation. In the latter case, a sensor such as a photosensor may be installed inside the work chamber to detect access of the operator's hand or a workpiece and a shield plate opening/closing mechanism also be provided. When the sensor detects when the hand or workpiece comes close thereto, it puts the shield plate operating mechanism into action to open or close the shield plate. Also in this case, a conveyance mechanism such as a belt conveyor may further be provided inside the work chamber to carry a workpiece between the entrance and exit of the work chamber. When the sensor detects when the workpiece is carried by the conveyance mechanism to near the exit, it puts the shield plate opening/closing mechanism into action to operate the shield plate. Also, a sealing material such as a gasket may be provided on the shield plate or work chamber wall to increase the airtightness of the work chamber when shielded by the shield plate.

In case a chemical process, chemical reaction, crystal growth, bio process, etc. are to be carried out in a clean environment, the work chamber is typically provided with an exhaust duct and a passive dust filter with no blower, which however depends upon what work or process is to be done in the work chamber. The exhaust duct and dust filter are typically installed in an upper portion of the work chamber. In this case, the clean unit is normally of an enclosed type to which however the present invention is not limited. On the other hand, in case a non-chemical process (physical measurement with the use of a surface probe microscope, inspection or assembling, for example) is carried out in the work chamber, the latter is typically provided with a pressure-control ventilator and an active dust filter with a blower (HEPA filter or ULPA filter, for example). Typically, the dust filter is provided in the upper portion of the work chamber, while the ventilator is in a lower portion of the side wall of the work chamber. In this case, the clean unit is normally of an open type in which the pressure inside the work chamber is controlled by the ventilator, to which however the present invention is not limited. In addition to the pressure-control ventilator, there are provided in the work chamber more than one or two holes through which electric wires or the like are to be led in or out as the case may be. The work chamber is adapted to guide a gas flowing out from there to an adsorber or remover using activated carbon or to both, and then to the inlet of the active dust filter. Further, an exhaust duct communicating with the outside atmosphere should preferably be connected to the adsorber and/or remover to adsorb harmful particles or to remove harmful gas included in the atmosphere, and then release the atmosphere thus cleaned to outside. Thus, the work chamber can be used for a bio process (cell culture, cell fusion, gene recombination, plant breeding, transformation or the like), chemical process or the like accompanied by generation of harmful particles or harmful gas. Also, the work chamber may be adapted to guide the gas flowing out through the ventilator to the inlet of the active dust filter, whereby the same dust filter can considerably improve the cleanliness of the work chamber. Most preferably for the improved cleanliness of the work chamber, the work chamber is adapted for guiding all the gas flowing out (100%) from the ventilator of the work chamber to the inlet of the active dust filter, which however is not always required. The cleanliness of the work chamber can effectively be improved even by designing the work chamber to guide part of the flowing-out gas to the inlet of the active dust filter. Typically, an airtight tube is connected directly to the work chamber and also to the inlet of the active dust filter to circulate the gas and assure the airtightness of the work chamber (turbo system). The work chamber is provided with work gloves as appropriate. The work gloves are normally provided in the front portion of the work chamber.

The clean unit is, for example, a nano-technology process unit or biotechnology process unit, which are usable for various processes.

Also, the clean unit is, for example, a draft, clean bench, glove box or the like, to which however the present invention is not limited.

The work chamber of a clean unit may be in any one selected from various forms as appropriate. More specifically, the form may be a rectangular parallelopiped or cube, modified rectangular parallelopiped or cube, sphere, hemisphere, ellipse, cylinder or the like. Basically, the internal volume of the work chamber is appropriately designed to meet an intended purpose. For the operator to be able to effect various kinds of work (carrying out a process, making maintenance such as cleaning, etc.) inside the work chamber with a pair of gloves on, for example, the work-chamber internal volume should desirably be such that the operator's hand inserted from outside the work chamber can desirably reach almost all corners of the entire working space in the work chamber. Generally, a dimension of less than 1 m and larger than 30 cm is selected for all the width, height and depth of the work chamber. Normally, a selected size of the work chamber, if too small, will possibly prevent the operator from making any work smoothly. In case work can be done without having to insert the hand from outside the work chamber, for example, in case the work can be effected automatically, or in case a workpiece is carried while being contained in the clean unit, the work chamber may be designed smaller.

The work chamber may be formed from a plate-shaped hard material or a balloon or a balloon-shaped soft material.

Depending upon an intended purpose, a compact apparatus may be accommodated inside the clean unit. More particularly, the apparatus is, for example, any one of various process units which will be described in detail later, lapping device, analyzer (for example, optical microscope, scanning probe microscope (SPM) such as a scanning electron microscope (SEM) or atomic force microscope (AFM)), reactor, microchemical system, microchemical reactor, exposure apparatus, etching apparatus, growth apparatus, working apparatus, sterilizer, particle filter, artificial light source, bio apparatus, food processor, inspection device, drive or the like. For breeding a cell or plant, the artificial light source should preferably be a light-emitting diode or semiconductor laser of which the spectrum half-value width is less than 30 nm. Especially, a pulse-driven semiconductor laser is used as the artificial light source.

Also, according to a fourth aspect of the present invention, there is provided a clean unit system formed from a plurality of clean units each having a work chamber that can be kept as a clean environment and which are connected to each other, at least one of the plurality of clean units including:

a work chamber that can be kept as a clean environment; and

connectors provided at at least one of the back, top and bottom of the work chamber and at at least one of the lateral sides of the work chamber, respectively.

In the above clean unit system, each of the plurality of clean units may include a work chamber that can be kept as a clean environment and connectors provided at at least one of the back, top and bottom of the work chamber and at at least one of the lateral sides of the work chamber, respectively, or the plurality of clean units may include together the clean units of the above-mentioned type and conventional clean units which can be connected only horizontally to each other.

The explanation of the clean unit according to the third aspect of the present invention is also true with the above clean unit including a work chamber that can be kept as a clean environment and connectors provided at at least one of the back, top and bottom of the work chamber and at at least one of the lateral sides of the work chamber, respectively.

The plurality of clean units includes, for example, a draft, clean bench, glove box and the like. When attention is focused on a process to be effected, the plurality of clean units includes a chemical process unit, non-chemical process unit, bio process unit and the like. Some of the plurality of clean units included in the clean unit system may be disposed to form a loop, for example.

The clean unit system according to the fourth aspect of the present invention is usable for various applications. With a nano-technology process unit or biotechnology process unit, for example, the clean unit system provides various process systems such as a nano-technology process system, biotechnology process system, etc. Further, with a combination of a nano-technology process unit and biotechnology process unit, the clean unit system provides a nano-technology/biotechnology platform. This is also true with a clean unit system which will be explained below. More particularly, the clean unit system is a material (inorganic or organic) processing system, device production system, cell bleeding system, plant bleeding system or the like.

According to the above fourth aspect of the present invention, at least one of the plurality of clean units has typically provided therein, for example, a compact process unit, analyzer, reactor, microchemical device, microchemical reactor, exposure device, etching device, bleeder, processing device, sterilizer, particle filter, artificial light source, bio device, food processor, inspection device, drive or the like which will be described below.

The process unit, analyzer, reactor, microchemical device, microchemical reactor, exposure device, etching device, bleeder, processing device, sterilizer, particle filter, artificial light source, bio device, food processor, inspection device, drive or the like to be installed in the clean unit should preferably be compact enough to be accommodated even in a small clean unit. For example, in case a total series of processes including from putting a workpiece into the clean unit up to output of a product is to be effected in the clean unit system or in case a series of processes forming a main part of the total series of processes is to be effected in the clean unit system, a group of compact process units that can be accommodated in the clean unit is used for various physical and chemical processes, respectively, included in the process flow. These process units may be provided removably in the clean unit or integrally with the latter.

For example, high-function devices such as the above-mentioned devices, semiconductor devices, etc. are produced through consistent processes from charging of a material up to output of a product. Such production has been achieved in the past by passing a substrate between high-precision apparatuses such as lithography apparatus, etching apparatus, etc. disposed in a large, highly-controlled clean room as having previously been described. In the present invention, however, downsized apparatuses developed based on the recent innovated technologies are adopted instead of the conventional apparatuses in such a clean room. For example, a desk-top scanning tunnel microscope (STM), atomic force microscope (AFM) or miniature scanning electron microscope (SEM) is used in place of the transmission electron microscope (TEM), conventional scanning electron microscope (SEM) or the like. In the photolithography apparatus included in the present invention, the exposure light source uses a semiconductor laser (see the document 10, for example) instead of the gas laser. For growth of thin films, a microchemical reactor (see the Document 11, for example) is used in place of the large-scale equipment such as a molecular beam epitaxy (MBE), metalorganic chemical vapor deposition (MOCVD) apparatus or the like. Also, metalization is effected using a metal plating machine, desk-top miniature deposition machine or the like. Further, a micro CVD (chemical vapor deposition) apparatus, micro RIE (reactive ion etching) apparatus, miniature spin coater, miniature baking apparatus and the like are used.

With the use of the smaller machines, the large clean room becomes unnecessary. That is, a series of all or main ones of the processes from charging of a substrate to output of a product lot with photolithography, forming of electrodes, surface checking, etc. in a process of producing semiconductors, or the like can completely be effected in a consistent manner in a series of concatenated clean units placed in an ordinary room, not in any large clean room, and including a local clean closed space (typically of a desk-top space size). Namely, owing to the compactness attained by replacement with the downsized apparatuses, it is possible to form the clean unit small enough to be installed on a table. Thus, when the clean units each having connectors provided at the back and at least one of the lateral sides of the work chamber are disposed in a zigzag line (winding line) or in a loop, the entire clean unit system will occupy only a small area. Further, the clean unit, air shower, clean mat and the like which have been indispensable for the operator working in the clean room become unnecessary. Therefore, almost all kinds of work can be effected in a local, very clean atmosphere with friendliness to both the human body and environment.

According to the aforementioned third and fourth aspects of the present invention, the connectors are provided each at at least one of the back, top and bottom and at least one of the lateral sides of the work chamber of the clean unit, so that one clean unit can be connected to another horizontally as well as at the back or vertically with a considerably improved freedom of connection between the clean units. The clean units can thus be connected to each other and disposed in a zigzag line or in a loop to form a clean unit system in which the clean units are positioned optimally for a process going to be effected and that occupies a minimum area. Also, with the connectors being provided each at at least one of the back, top and bottom and at least one of the lateral sides of the work chamber of the clean unit and ventilator and active dust filter being provided in the work chamber, the freedom of connection between the clean units is not only improved considerably but the inner space of the work chamber can be kept as a clean environment.

Also, the clean units connected to each other and disposed in a non-single line, zigzag line, branching pattern, loop or in a combination of two or more of these patterns of disposition can form a clean unit system having the clean units positioned optimally for a process going to be effected and which occupies a minimum area.

Also, a clean unit system formed from the clean units connected to each other and disposed in such a zigzag line to be accommodated in a predetermined limited area is optimum for a process going to be effected and occupies a minimum area.

Also, a clean unit system formed from a plurality of clean units connected to each other and disposed in a mosaic pattern is optimum for a process flow including a wide variety of processes.

Also, since some of a plurality of clean units, connected to each other and disposed in a loop, can effect processes of the same type emerging more than once in a total series of process flows in the same clean unit, so the number of clean units necessary for the same type of process can be reduced.

Also, a plurality of clean units each having compact apparatuses of different types provided therein, of which some are connected to each other and disposed in a zigzag line or in a loop to consistently perform all or main part of the processes in a total series of process flows, can efficiently perform processes such as material processing, device production, cell breeding, plant breeding, etc.

Also, the exhaust duct and passive dust filter provided in the work chamber of the clean unit can keep the work chamber inside as a clean environment without use of any blower.

Here, consideration will be made of a clean unit having a box-shaped work chamber of which the inside is kept as a clean environment using a ventilator and active dust filter with a blower (HEPA filter, ULPA filter or the like, for example). The clean unit may have or have not connectors. In this case, the dust density n(t) in the work chamber is given as the following expression (1) on the consumption that the gas flow rate of the dust filter is V, volume of the work chamber is V₀, internal area is S, desorption rate of dust particles per area and time is σ, dust density in the environment where the clean unit is installed is N₀ and dust collection efficiency of the dust filter is γ:

$${V}_{o} \frac{ⅆ n ( t )}{ⅆ t} = S σ - n ( t ) V + {N}_{o} {V ( 1 - γ )}^{2} \qquad ( 1 )$$

When it is defined that:

$$\begin{matrix}{α}_{c} = \frac{S σ}{{V}_{o}} + {( 1 - γ )}^{2} \frac{V}{{V}_{o}} {N}_{o} \\ and & ( 2 ) \\ {β}_{c} = \frac{V}{{V}_{o}} & ( 3 )\end{matrix}$$

the dust density is given by the following expression (4):

$$n ( t ) = \frac{{α}_{c}}{{β}_{c}} + ( {N}_{0} - \frac{{α}_{c}}{{β}_{c}} ) {ⅇ}^{- {β}_{c} t} \qquad ( 4 )$$

It will be a linear function of the dust density in the atmosphere even if the time passes. That is, the dust density will greatly depend upon the environment where the clean unit is installed.

Next, the aforementioned turbo system will be considered. It is assumed here that an airtight tube connected directly to the work chamber is connected to the inlet of the active dust filter to circulate a gas and the turbo system is airtight. In this case, the dust density n(t) is given by the following expression (5):

$$\begin{matrix}{V}_{o} \frac{ⅆ n ( t )}{ⅆ t} = S σ - n ( t ) V + n ( t ) V ( 1 - γ ) \\ = S σ - γ Vn ( t )\end{matrix} \qquad ( 5 )$$

When it is defined that:

$$\begin{matrix}{α}_{n} = \frac{S σ}{{V}_{o}} \\ and & ( 6 ) \\ {β}_{n} = \frac{γ V}{{V}_{o}} & ( 7 )\end{matrix}$$

the dust particle density is given by the following expression (8):

$$n ( t ) = \frac{{α}_{n}}{{β}_{n}} + ( {N}_{0} - \frac{{α}_{n}}{{β}_{n}} ) {ⅇ}^{- {β}_{c} t} \qquad ( 8 )$$

Since the second term of the expression (8) rapidly approximates to zero as the time passes, only the first term, that is, αn/βn=(Sσ/V₀)/(γV/V₀)=Sσ/γV, will remain. Since this first term includes no dust density of the atmosphere, it will be apparent that an ultimate cleanliness can be assured, not depending upon the environment where the clean unit is installed. The feature of a clean unit using no turbo system is the cleanliness of the work chamber depends upon 1-γ or its power (1-γ)ⁿ while the cleanliness of the work chamber of a clean unit using the turbo system depends upon 1/γ. Also, it is important to minimize Sσ/γV.

Also, according to a fifth aspect of the present invention, there is provided a clean unit in which an active dust filter is used to keep a work chamber as a clean environment, wherein the cleanliness of the work chamber depends upon 1/γ where γ is the dust collection efficiency of the dust filter.

Typically, the dust filter is a HEPA or ULPA filter and constructed for all the gas flowing out of the work chamber to enter the inlet of the active dust filter. More particularly, an airtight tube may be connected directly to the work chamber and also connected to the inlet of the dust filter to circulate the gas and assure the airtightness of the clean unit. Preferably for execution of a chemical process in the clean unit, use of a dust filter suitable for use with the chemical process and connecting an adsorbent source or adsorption tower to the tube permit to provide a closed system that can remove a harmful substance and also continuously provide a clean environment without having to connect the clean unit to outside via a duct or the like. To minimize emission of dust or powder dust from the inner surface of the work chamber, at least part of the inner surface of the work chamber may preferably be covered with an adhesive sheet and re-covered with a fresh adhesive sheet after the work chamber having been used for a predetermined period, for example. In case a multi-layer adhesive sheet is used, a clean sheet surface may be exposed by peeling one sheet layer off the adhesive sheet at each elapse of such a predetermined period. Also, the inner surface of the work chamber may be smoothed not to have any Fourier component of a surface roughness on the same order as the diameter of the dust particle to be removed from the work chamber, to thereby minimize the adsorption of dust particles having the size of the to-be-removed dust particles to the inner surface of the work chamber.

The aforementioned construction the clean unit or clean unit system according to the third or fourth aspect of the present invention and explanation made in connection with the construction are also true with, or applicable to, the fifth aspect of the present invention unless the fifth aspect is different in character from the third and fourth aspects.

Also, two or more of the aforementioned aspects of the present invention may be combined as appropriate.

The foregoing and other features, aspects and advantages of the present invention will become apparent from the following detailed description of embodiments of the present invention when taken in conjunction with the accompanying drawings.

Additional features and advantages are described herein, and will be apparent from, the following Detailed Description and the figures.

### BRIEF DESCRIPTION OF THE FIGURES

FIGS. 1A, 1B and 1C schematically illustrate an organic solar cell according to a first embodiment of the present invention.

FIGS. 2A, 2B and 2C are schematic diagrams for explaining how to produce an organic solar cell according to a second embodiment of the present invention.

FIGS. 3A, 3B and 3C schematically illustrate the organic solar cell as the second embodiment of the present invention.

FIGS. 4 and 5 are schematic diagrams for explaining how to produce the organic solar cell as the second embodiment of the present invention.

FIG. 6 schematically illustrates an example layout of the organic solar cells as the second embodiment of the present invention.

FIGS. 7A, 7B and 7C, 8 and 9 schematically illustrate a solar cell according to a third embodiment of the present invention.

FIGS. 10A, 10B and 10C schematically illustrate a solar cell according to a fourth embodiment of the present invention.

FIG. 11 schematically illustrates a solar cell system using the solar cells as the fourth embodiment of the present invention.

FIGS. 12 and 13 schematically illustrate a solar cell according to a fifth embodiment of the present invention.

FIGS. 14 and 15 schematically illustrate a solar cell system using solar cells according to a sixth embodiment of the present invention.

FIGS. 16A, 16B and 16C are a plan view, front view and side elevation, respectively, of a clean unit according to a seventh embodiment of the present invention.

FIGS. 17A, 17B and 17C are a plan view, front view and side elevation, respectively, of the transfer box attached to the clean unit as the seventh embodiment of the present invention.

FIGS. 18A and 18B are a side elevation and front view, respectively, of the connection between the clean unit as the seventh embodiment of the present invention and a transfer box.

FIGS. 19A and 19B are a side elevation and front view, respectively, of a charge/discharge box installed to the clean unit as the seventh embodiment of the present invention.

FIGS. 20A and 20B are a side elevation and front view, respectively, for explaining how to shield an unused connector opening of the clean unit as the seventh embodiment of the present invention.

FIGS. 21A, 21B and 21C are a plan view, front view and side elevation, respectively, of a clean unit according to an eighth embodiment of the present invention.

FIG. 22 schematically illustrates a clean unit system according to a ninth embodiment of the present invention.

FIG. 23 schematically illustrates a clean unit system according to a tenth embodiment of the present invention.

FIGS. 24A, 24B and 24C are a plan view, front view and side elevation, respectively, of a clean unit according to an eleventh embodiment of the present invention.

FIGS. 25A, 25B and 25C are a plan view, front view and side elevation, respectively, of a clean unit according to a twelfth embodiment of the present invention.

FIG. 26 is a front view of a clean unit according to a thirteenth embodiment of the present invention.

FIG. 27 schematically illustrates results of cleanliness test made on the clean unit shown in FIGS. 24A, 24B and 24C.

### DETAILED DESCRIPTION

The present invention will be explained in detail below concerning the embodiments thereof with reference to the accompanying drawings.

First, a functional device as the first embodiment of the present invention will be explained herebelow:

The first embodiment of the present invention is a functional device having a periodic structure, that is, a structure in which the time is continuously factored and to which access is to be made from a direction perpendicular to the direction in which the time is factored. This functional device is formed from a slice of a periodic spiral structure including a strip- or ribbon-shaped conductor layer of a metal or the like and a non-metal layer having a thickness more than double that of the conductor layer, and which accesses light (sunlight or the like) from a direction intersecting, preferably perpendicular to, the slice.

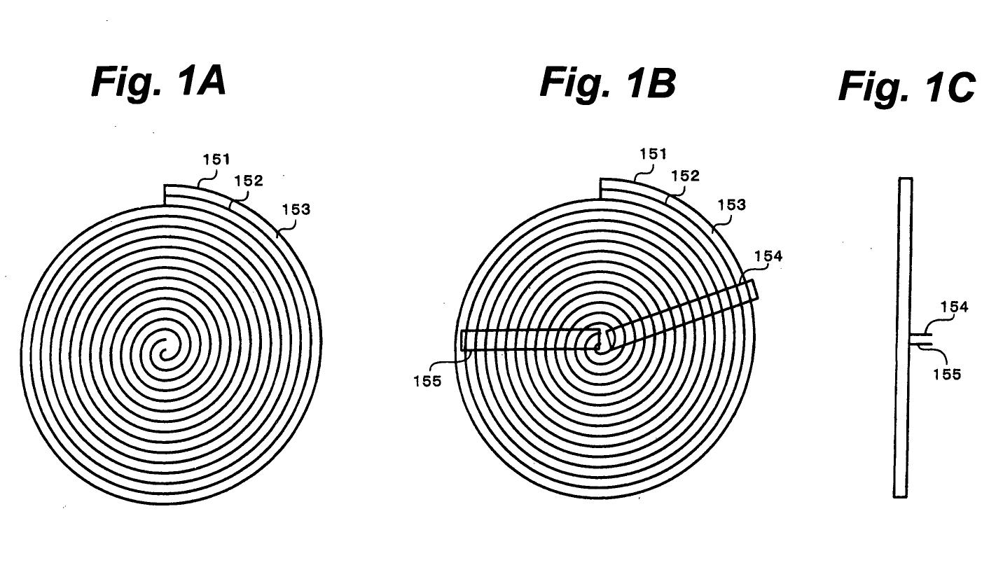

More specifically, the functional device is an organic solar cell as the first embodiment of the present invention as shown in FIGS. 1A, 1B and 1C which are a front view, rear view and side elevation, respectively. As shown in FIGS. 1A, 1B and 1C, the organic solar cell is formed from a spiral structure composed of an anode 151 and cathode 152 with an organic semiconductor layer 153 laid between the anode 151 and cathode 152. The solar cell has the general form of a thin disk as shown. An insulating layer (not shown) is provided where the anode 151 and cathode 152 are in a back-to-back relation to electrically insulate the anode 151 and cathode 152 from each other. On the back of the organic solar cell, linear output electrodes 154 and 155 are provided radially from the center of the solar cell. It should be noted that the output electrode 154 is in contact with the anode 151, while the output electrode 155 is in contact with the cathode 152.

The organic semiconductor layer 153 has a structure of heterojunction or bulk-heterojunction type. In the organic semiconductor layer 153 of the heterojunction type structure, a p-type organic semiconductor film and an n-type one are joined to each other to be in contact with the anode 151 and cathode 152, respectively. The organic semiconductor layer 153 of the bulk-heterojunction type structure has a fine structure, and formed from a mixture of p-type organic semiconductor molecules and n-type ones, and the p-type organic semiconductor film and n-type one are in such an intricate relation as to be in contact with each other. The organic semiconductor layer 153 may be formed from any one of common materials having ever been reported as those for the organic solar cell, more particularly, polyacetylene (preferably a double-substituted polyacetylene), poly(p-phenylenevinylene), poly(2,5-thienylenevinylene), polypyrrole, poly(3-methylthiophene), polyaniline, poly(9,9-dialkylfluorene) (PDAF), poly(9,9-dioctylfluorene-co-bithiophene) (F8T2), poly(1-hexyl-2-phenylacetylene) (PhₓPA) (as a light-emitting material to emit blue light), poly(diphenylacetylene) derivative (PDPA-nBu)(as a light-emitting material to emit green light), poly(pyridine) (PPy), poly(pyridyl vinylene) (PPyV), thiano-substituted poly(p-phenylene vinylene) (CNPPV), poly(3,9-di-tert-buthylindeno[1,2-b]fluorene (PIF) and the like. For these organic semiconductor dopants, alkali metal (Li, Na, K or Cs) may be used as donor, halogen (Br₂, I₂ or Cl₂), Lewis acid (BF₃, PF₅, AsF₅, SbF₅ or SO₃), transition metal halide (FeCl₃, MoCl₅, WCl₅ or SnCl₄) be used as acceptor, and TCNE or TCNQ be used as organic acceptor molecule. Also, for the dopant ion used in the electrochemical doping, tetraethyl ammonium ion (TEA⁺), tetrabutyl ammonium ion (TBA⁺), Li⁺, Na⁺ or K⁺ may be used as cation and ClO₄⁻, BF₄⁻, PF₆⁻, AsF₆⁻, SbF₆⁻ or the like be used as anion.

Further, a polyeletrolyte may be used as the organic semiconductor layer 153. More specifically, the polyelectrolytes usable as the organic semiconductor layer 153 include sulfonate polyaniline, poly(thiophene-3-acetic acid), sulfonate polystyrene, poly(3-thiophene alkane sulfonate), etc. as polyaniline, and polyallyl amine, poly(p-phenylene-vinylene) precursor polymer, poly(p-methyl pyridinium vinylene), protonated poly(p-pyridilvinylene), proton(2-N-methyl pyridinium acetylene), etc. as polycation.

The anode 151 and cathode 152 should preferably be made of metals different in work function from each other, respectively. More specifically, the anode 151 is made of Au or Ni, while the cathode 152 is of Al.

The size of the each part of the solar cell is as follows, for example. The organic semiconductor layer 153 is 70 to 100 nm thick, and the anode 151 and cathode 152 are about 100 nm in thickness. The height (thickness) of the organic solar cell, that is, the height of the organic semiconductor layer 153, is designed large enough for light incident from a direction perpendicular to the surface of the organic solar cell to be almost all or completely absorbed for photoelectric conversion. More specifically, the selected height ranges from about a few μm to 1 mm.

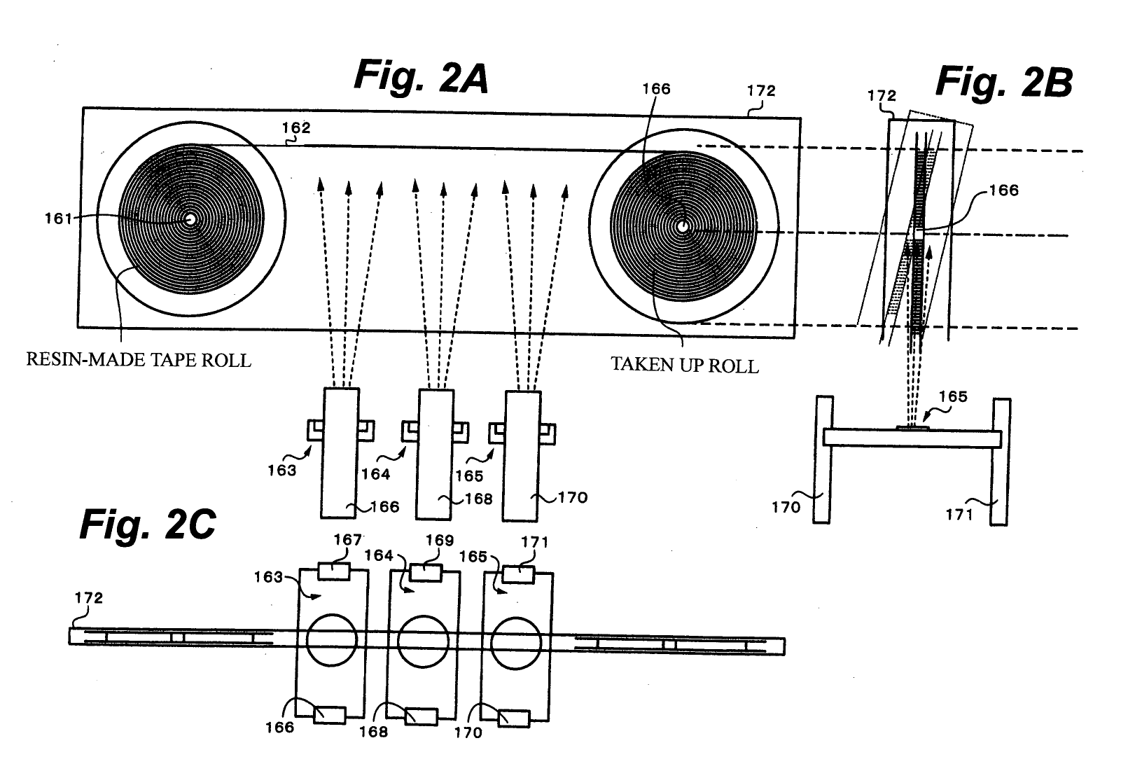

Next, how to produce the organic solar cell will be explained by way of example. It should be noted that in this solar cell, the p-type organic semiconductor film and n-type one are joined to each other in the organic semiconductor layer 153 (heterojunction structure). FIGS. 2A, 2B and 2C are a front view, side elevation and plan view, respectively, to show a vacuum evaporation apparatus to be used for production of the organic solar cell.

First, with a thin, flat tape-shaped resin-made base film 162 having a predetermined width, for example, being wound on a supply roller 161, a metal for the cathode is vaporized from an evaporation source 163 to form the cathode 152 on one side of the resin-made base film 162 as shown in FIGS. 2A, 2B and 2C. Next, an n-type organic semiconductor is vaporized from an evaporation source 164 to form an n-type organic semiconductor film on the one side of the resin-made base film 162. Then, a p-type organic semiconductor is vaporized from an evaporation source 165 to form a p-type organic semiconductor film on the one side of the resin-made base film 162. Further, the metal for the anode is vaporized from the evaporation source 163 to form the anode 151 on the one side of the resin-made base film 162. Then, the deposited films thus deposited are taken up on a take-up roller 166. In this case, the resin-made base film 162 should be a heat- or light-separable one. That is, the resin-made base film 162 has to be separated from the deposited films. In order to prevent the resin-made base film 162 from being wound onto the take-up roller 166 together with the cathode 152, n-type organic semiconductor film, p-type organic semiconductor film and anode 151 going to be formed spiral on the take-up roller 166, the resin-made base film 162 is pressed at the other side thereof with a hot roller, or irradiated at the other side with light, just before it is wound onto the take-up roller 166. Thus, the resin-made base film 162 is separated from the cathode, semiconductor films and cathode. In FIG. 2, reference numerals 166 to 171 indicate electrodes to energize the evaporation sources 163 to 165. The roller 161 having the resin-made base film 162 wound thereon and the take-up roller 166 are accommodated as a whole in a housing 172 open at the bottom thereof so that evaporation beams from the evaporation sources 163 to 165 will be irradiated from the open bottom of the housing 172 to the resin-made base film 162.

As shown in FIG. 2B, all the housing 172 and rollers 161 and 166 accommodated in the housing 172 can be tilted from a vertical plane indicated with a dotted line, so that the evaporation can be made obliquely as appropriate.

Also, a metallic shield plate (not shown) having an opening of 1 to 3 mm in diameter, for example, formed therein is actually formed at each of the evaporation sources 163 to 165 to minimize the heat radiation from the evaporation sources 163 to 165 to the resin-made base film 162.

According to this first embodiment, the anode 151 and cathode 152 are formed spiral with the organic semiconductor layer 153 being laid between them to provide a thin, disk-shaped organic solar cell. Thus, the p-n junction area per unit area of the organic solar cell is extremely large so that light incident perpendicularly upon the surface of the organic solar cell can be absorbed in an increased light absorption area of the organic semiconductor layer 153. Generally, the organic semiconductor layer 153 is high in electrical resistance, but the electrical resistance can be reduced sufficiently by forming the organic semiconductor layer 153 sufficiently thin. Thus, it is possible to provide an organic solar cell being highly flexible and having a high efficiency of photoelectric conversion.

Next, a second embodiment of the present invention will be explained:

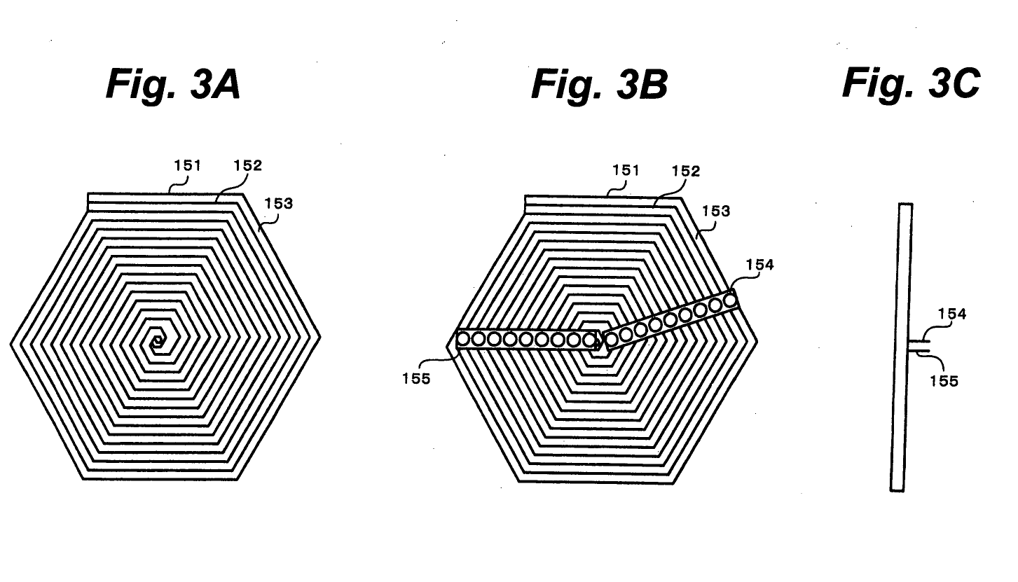

FIGS. 3A, 3B and 3C which are a front view, rear view and side elevation, respectively, schematically illustrate together an organic solar cell as the second embodiment. As shown in FIGS. 3A, 3B and 3C, this organic solar cell is formed hexagonal-spiral from the anode 151 and cathode 152 with the organic semiconductor layer 153 being laid between the latter. Namely, it has the general form of a thin, hexagonal plate. In other respects, this organic solar cell is similar to that as the first embodiment.

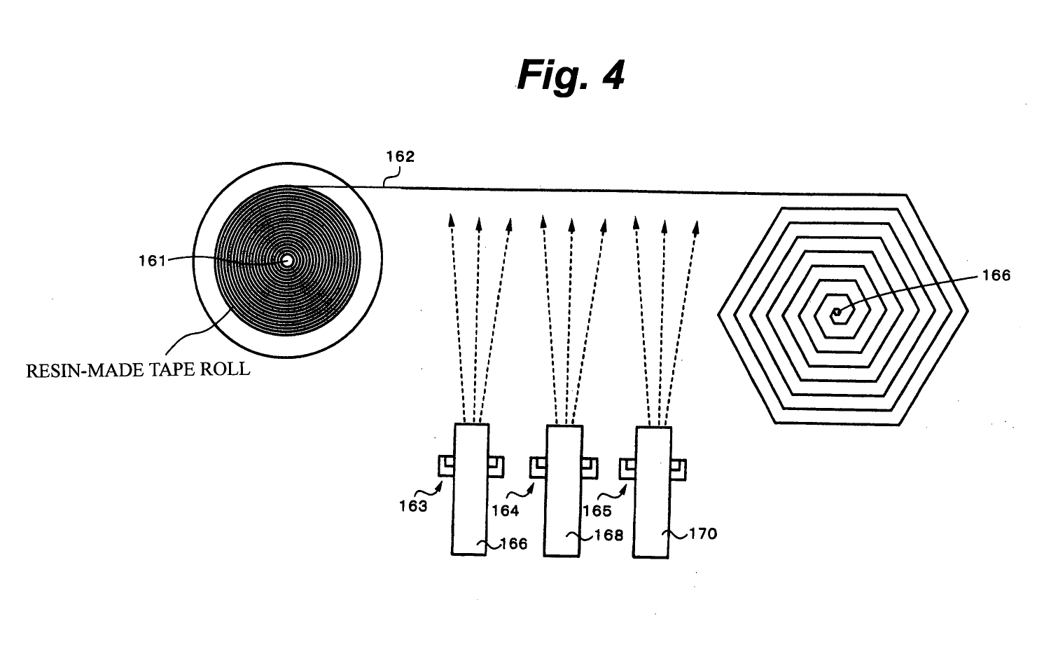

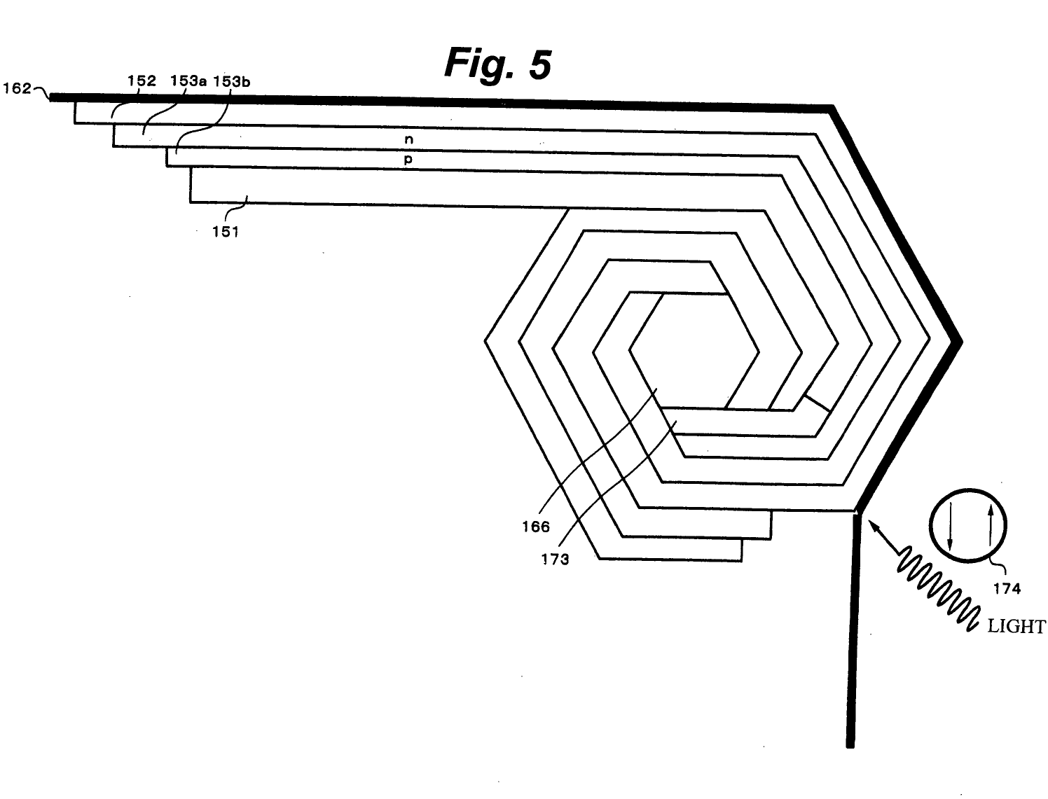

Here will be explained how to produce this organic solar cell by way of example. It should be noted that the organic semiconductor layer 153 has the heterojunction type structure in which a p-type semiconductor film and n-type semiconductor film are joined to each other. FIG. 4 shows a vacuum evaporation apparatus used for production of this organic solar cell, and FIG. 5 shows winding of the resin-made base film 162 having the deposited films thereon onto the take-up roller 166.

With a thin, flat tape-shaped resin-made base film 162 having a predetermined width, for example, being wound on a supply roller 161, a metal for the cathode is vaporized from an evaporation source 163 to form the cathode 152 on one side of the resin-made base film 162 as shown in FIG. 4. Next, an n-type organic semiconductor is vaporized from an evaporation source 164 to form an n-type organic semiconductor film 153a on the one side of the resin-made base film 162. Then, a p-type organic semiconductor is vaporized from an evaporation source 165 to form a p-type organic semiconductor film 153b on the one side of the resin-made base film 162. Further, the metal for the anode is vaporized from the evaporation source 163 to form the anode 151 on the one side of the resin-made base film 162. Then, the deposited films thus deposited are taken up on a hexagonal take-up roller 166. In other respects, this method of organic solar cell is similar to that having been described above concerning the first embodiment.

In FIG. 5, a reference number 173 indicates an insulating film for providing electrical insulation between the p- and n-type organic semiconductor films. The insulating film 173 is formed just before the metal for the anode is vaporized from the evaporation source 163.

In order to prevent the resin-made base film 162 from being wound onto the hexagonal take-up roller 166 together with the cathode 152, n-type organic semiconductor film 153a, p-type organic semiconductor film 153b and anode 151 going to be formed spiral on the take-up roller 166, the resin-made base film 162 is pressed at the other side thereof with a hot roller 174, or irradiated at the other side with light, just before it is wound onto the take-up roller 166. Thus, the resin-made base film 162 is separated from the cathode, semiconductor films and cathode.

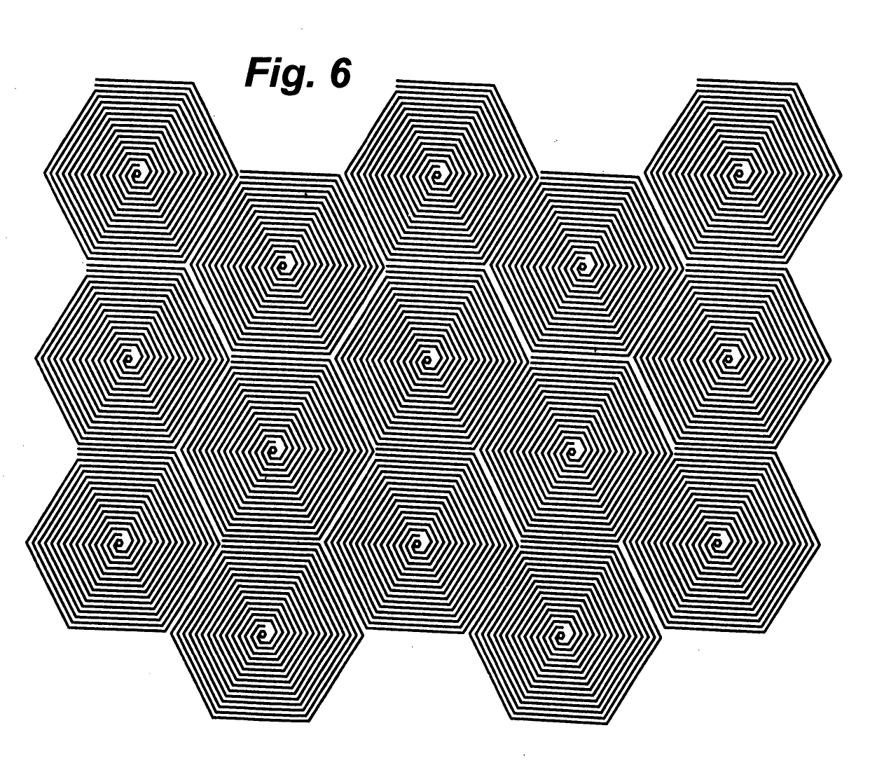

The second embodiment is similarly advantageous to the first embodiment and also advantageous as follows. Since the organic solar cell as the second embodiment has the general form of a hexagon, a plurality of the organic solar cells can be bedded in a plane with no gaps among them as shown in FIG. 6. Thus, it is possible to increase the production of electricity per unit area considerably.

Next, a solar cell according to a third embodiment will be explained:

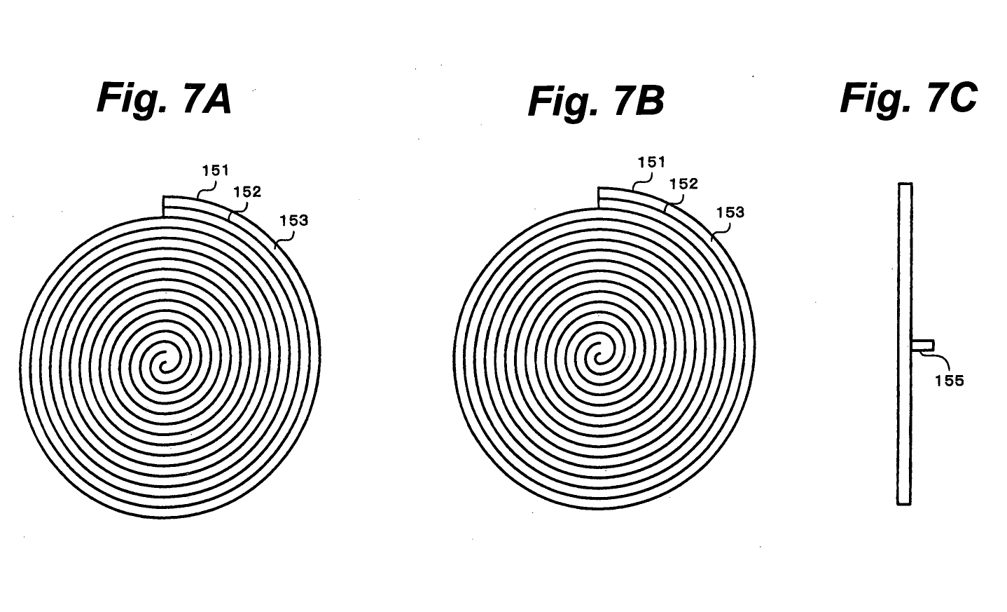

FIGS. 7A, 7B and 7C which are a front view, rear view and side elevation, respectively, schematically illustrate together a solar cell as the third embodiment. As shown in FIGS. 7A, 7B and 7C, this solar cell is formed spiral from an anode 151 and cathode 152 with a p-n junction of a p-type semiconductor layer and n-type semiconductor layer being laid between them. Namely, it has the general form of a thin disk. Each of the p- and n-type semiconductor layers may be of an inorganic or organic semiconductor.

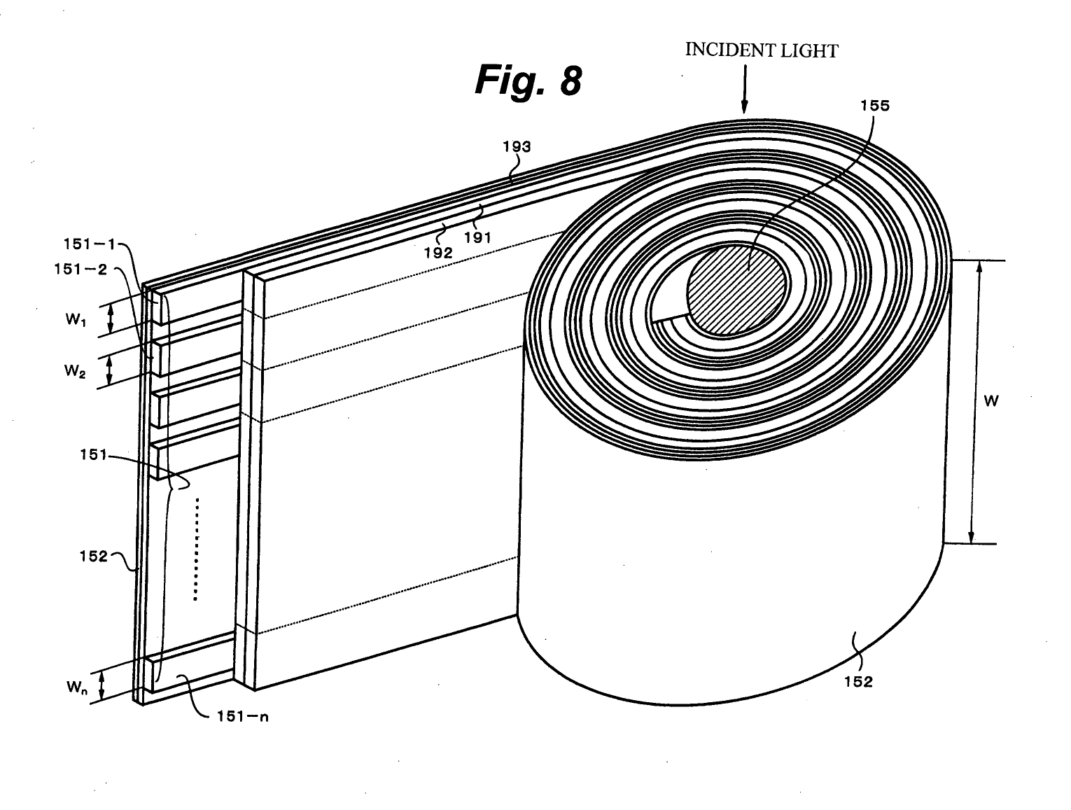

FIG. 8 schematically illustrates the solar cell in detail. In FIG. 8, a reference numeral 191 indicates a p-type semiconductor film and 192 indicates an n-type semiconductor film. As shown in FIG. 8, an insulating layer 193 of various insulating materials such as a resin is provided where the anode 151 and cathode 152 are in a back-to-back relation to electrically insulate the anode 151 and cathode 152 from each other. In this embodiment, the cathode 152 is a whole surface electrode and in ohmic contact with the n-type semiconductor layer 192, while the anode 151 includes n elongated micro electrodes 151-1 to 151-n isolated in the direction of the disk thickness (W) from each other. These micro anodes 151-1 to 151-n have widths W₁, W₂, . . . , Wₙ, respectively, which may be equal to each other or different from each other.

The p- and n-type type semiconductor layers 191 and 192 have a band gap E_{g} between them. The band gap E_{g} is decreased stepwise (in n steps (n≧2)) in the direction of the disk thickness from the light-incident surface. Namely, the band gaps E_{g} are E_{g1}, E_{g2}, . . . , E_{gn} (E_{g1}>E_{g2}> . . . >E_{gn}) in this order from the light-incident side. A zone in which the band gap E_{g} between the p- and n-type semiconductor layers 191 and 192 is E_{gk}(1≦k≦n) is called “E_{gk} zone”. In this E_{gk} zone, the p-semiconductor layers 191 and micro anode 151-k are in ohmic contact with each other. These E_{gk} zones may be integral with each other or isolated from each other. A structure in which the E_{gk} zone is laid between the micro anode 151-k and cathode 152 forms a micro solar cell. The solar cell as the third embodiment is formed from n such micro solar cells with the cathode 152 being taken as a common electrode.

The band gap E_{gk} can be set as will be explained below. In the entire or main wavelength range of a sunlight spectrum of AM1.5 (including a portion in which the incident energy is high), the wavelength is divided into n zones. Then, the zones are sequentially numbered 1, 2, . . . , n starting at the short-wavelength side, and an E_{gk} zone is selected equally to the minimum photon energy in a k-th zone. Thus, when a photon having the photon energy in the k-th zone is incident upon the E_{gk} zone, a pair of electron and positive hole takes place for photoelectric conversion. Also in this case, a depth from the light-incident surface to the E_{gk} zone is selected so that the photon having the photon energy in the k-th zone will arrive at each E_{gk} zone and be absorbed sufficiently. Thus, the sunlight incident upon the light-incident surface of the solar cell is first incident upon the E_{g1} zone where photon energies larger than E_{g1} in its spectrum will be absorbed for photoelectric conversion, then upon the E_{g2} zone where photon energies larger than E_{g2} and smaller than E_{g1} will be absorbed for photoelectric conversion, and finally upon the E_{gn} zone where photon energies larger than E_{gn} and smaller than E_{gn-1} will be absorbed for photoelectric conversion. As a result, light in almost the entire or main wavelength range of the sunlight spectrum can be photoelectrically converted.

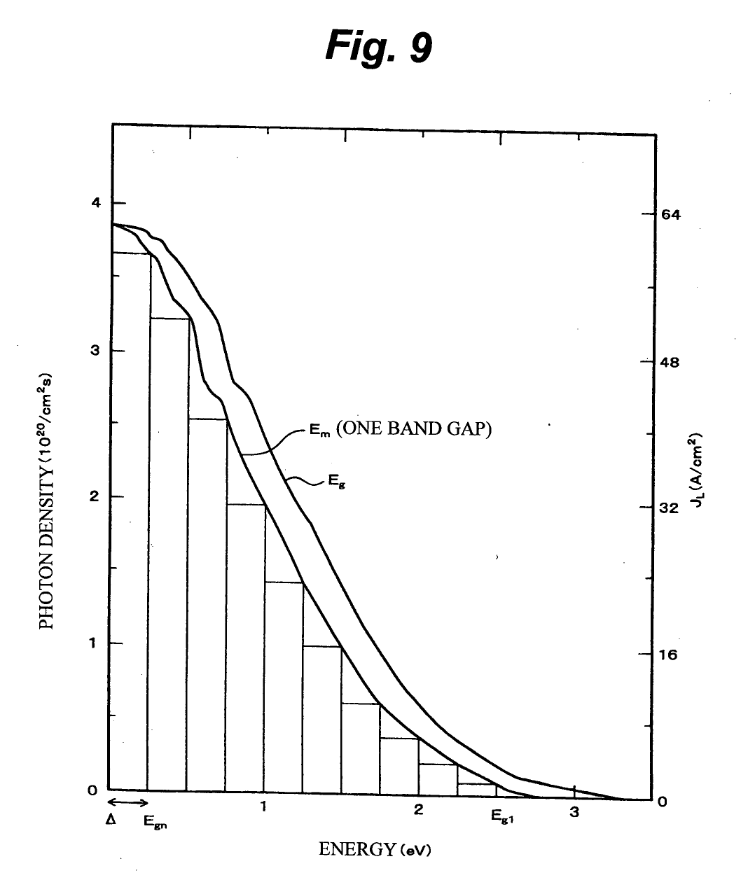

An example of ideal setting of the E_{gk} zone will be explained herebelow. FIG. 9 shows the relation between a photon density nₚₕ and photon energy hv of the sunlight spectrum of AM1.5. It is assumed here the photon energy of the sunlight spectrum of AM1.5 is equally divided into 10 zones each of an energy width Δ. The theoretical maximum efficiency of photoelectric conversion is as high as about 65%, which is more than 31% of the theoretical maximum efficiency of photoelectric conversion of a conventional solar cell of E_{g}=1.35 eV, for example.

Each E_{gk} zone can be set by changing the composition of a semiconductor forming each E_{gk} zone. More specifically, the E_{gk} zones are formed from different types of semiconductors. In case the semiconductors used are inorganic ones, the E_{gk} zones are formed as follows. In case the photon energy is divided into two zones (n=2), the E_{g1} zone is formed from GaAs (Eg=1.43 eV) and E_{g2} zone is formed from Si (E_{g}=1.11 eV), for example. In case n=3, the E_{g1} zone is formed GaP (E_{g}=2.25 eV), E_{g2} zone is formed from GaAs (E_{g}=1.43 eV) and E_{g3} zone is formed from Si (E_{g}=1.11 eV), for example. In case n=4, the E_{g1} zone is formed from GaP (E_{g}=2.25 eV), E_{g2} zone is formed from GaAs (E_{g}=1.43 eV), E_{g3} zone is formed from Si (E_{g}=1.11 eV) and E_{g4} zone is formed from Ge (E_{g}=0.76 eV). Further, the E_{gk} zones when the photon energy is divided into a range of n to 10 may be formed from GaInNₓAs₁₋ₓ and GaInNₓP₁₋ₓ just by controlling the value x. In addition, the E_{gk} zone may be formed from a II-VI compound semiconductor well known to show large bowing when Te is included therein.

The method of producing this solar cell is similar to the producing method for the first embodiment.

In case a solar battery system is formed from a plurality of the solar cells according to the third embodiment, the micro anodes 151-k of the solar cells laid in a line are connected to each other to output a voltage from the micro anodes 151-k of the last one of the solar cells laid in each line.

The third embodiment is similarly advantageous to the first embodiment, and also has the following advantage. That is, the conventional amorphous Si solar cell, for example, cannot utilize light having a wavelength of which the photon energy in the sunlight spectrum is smaller than 1.12 eV, but the solar cell according to the third embodiment is enabled by the design of the E_{gk} zone to utilize all or main part of light in the sunlight spectrum, to thereby permitting to attain a dramatically improved efficiency of photoelectric conversion.

Next, a solar cell according to a fourth embodiment will be explained:

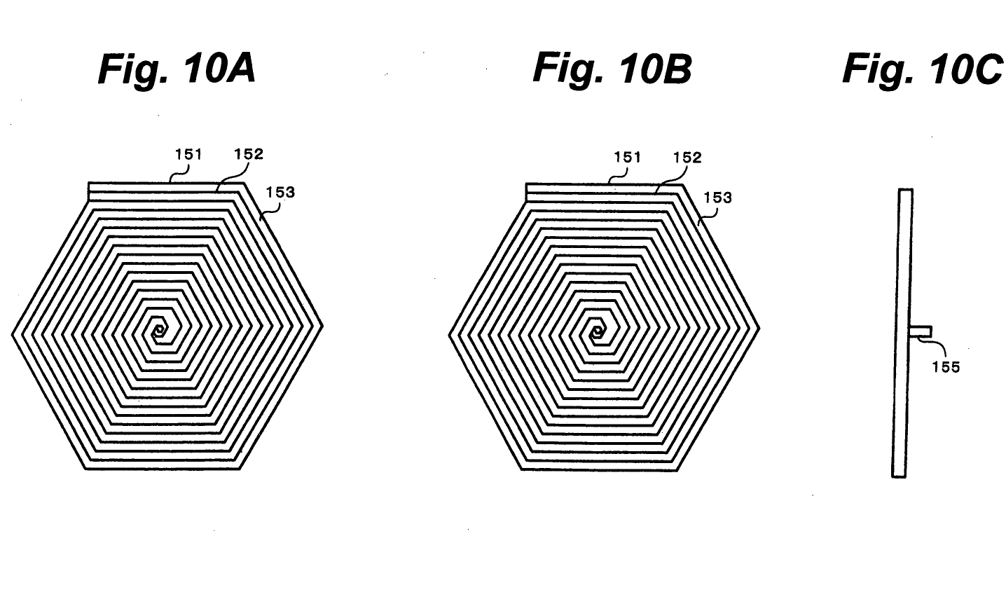

FIGS. 10A, 10B and 10C which are a front view, rear view and side elevation, respectively, schematically illustrate together a solar cell as the fourth embodiment. As shown in FIGS. 10A, 10B and 10C, this solar cell is formed spiral from an anode 151 and cathode 152 with a p-n junction of a p-type semiconductor layer 191 and n-type semiconductor layer 192 being laid between them. Namely, it has the general form of a thin hexagonal plate. In other respects, the fourth embodiment is similar to the third embodiment.

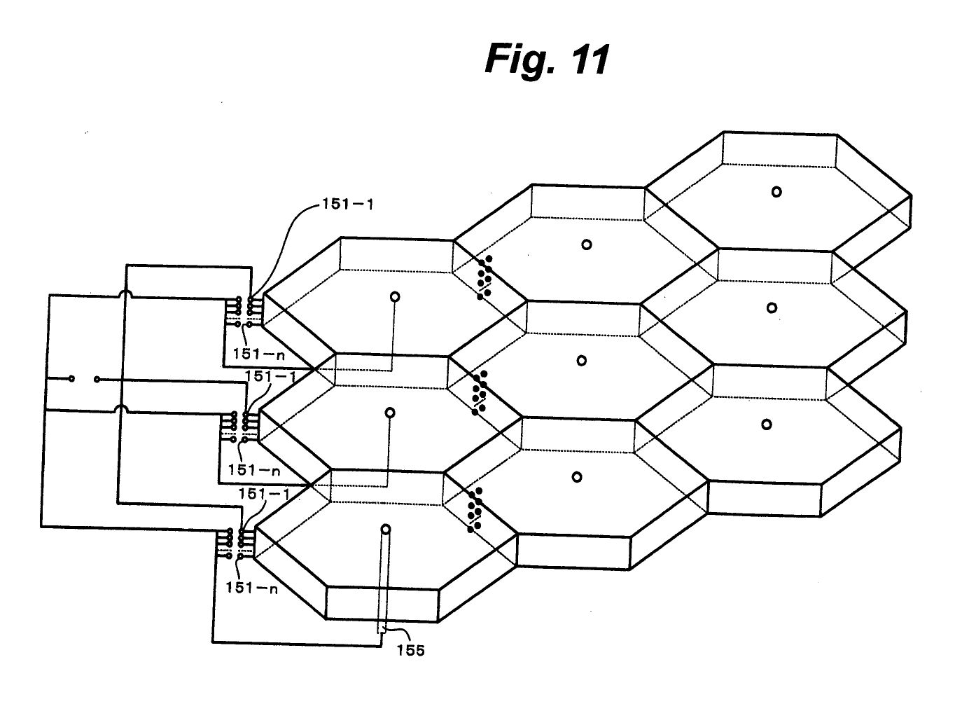

In case a solar battery system is formed from the hexagonal solar cells bedded in a plane with no gaps among them, the micro anodes 151-k of the solar cells laid in a line are connected to each other to output a voltage from the micro anode 151-k of the last one of the solar cells laid in each line. In this case, the micro solar cells in the E_{gk} zones of the solar cells laid in one line are connected in parallel to each other. FIG. 11 shows the solar battery system.

The fourth embodiment is similarly advantageous to the third embodiment, and also has the following advantage. That is, since the solar cell according to the fourth embodiment is formed hexagonal, the solar cells can be bedded in a plane with no gaps among them as shown in FIG. 6. Thus, the efficiency of photoelectric conversion of each solar cell can be increased dramatically and also the production of electricity per unit area can also be increased dramatically.

Next, a solar cell according to a fifth embodiment of the present invention will be explained.

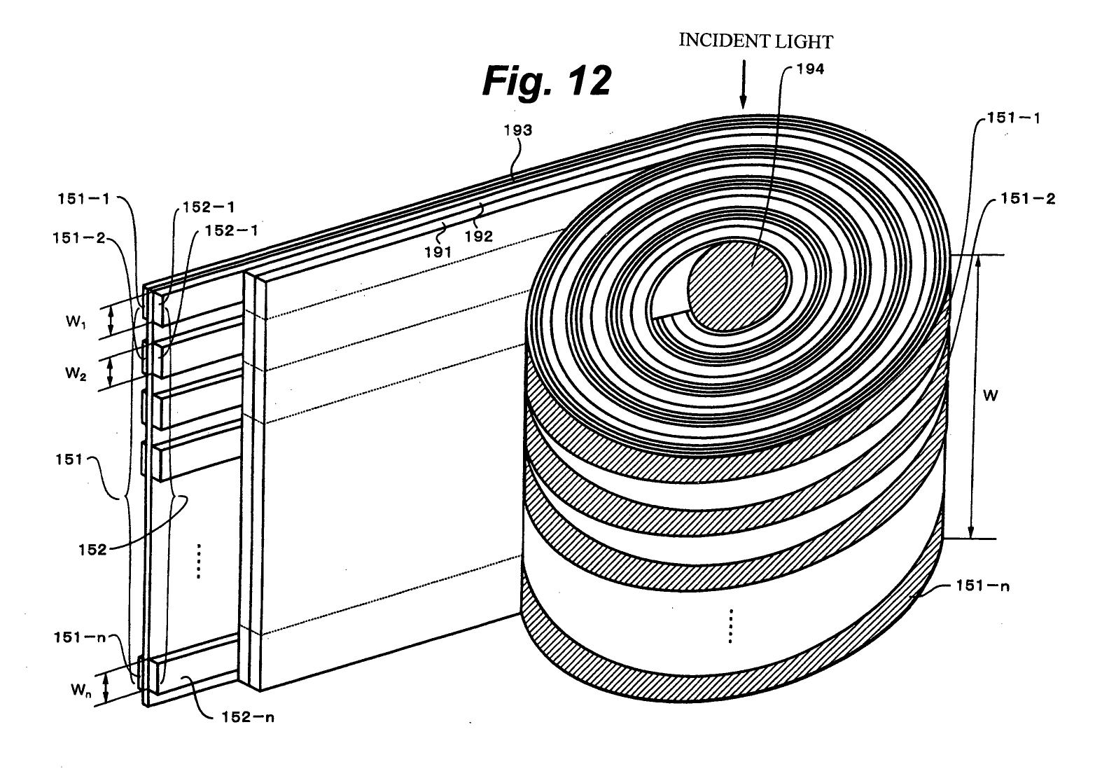

As shown in FIG. 12, the solar cell is formed spiral from an anode 151 and cathode 152 with a p-n junction of a p-type semiconductor layer and n-type semiconductor layer being laid between them, which is similar to the third embodiments except that a center shaft 194 is provided as a take-up shaft at the anode side so that the n-type semiconductor layer 192 is wound on the shaft more early than the p-type semiconductor layer 191 and that the anode 151 includes n elongated micro anodes 151-1 to 151-n separated from each other in the direction of hexagonal-plate thickness (W) and also the cathode 152 includes n elongated micro cathodes 152-1 to 152-n separated from each other in the direction of hexagonal-plate thickness (W). The widths of the micro cathodes 152-1 to 152-n are W₁, W₂, . . . , Wₙ, respectively. In other respects, the fifth embodiment is similar to the third embodiment.

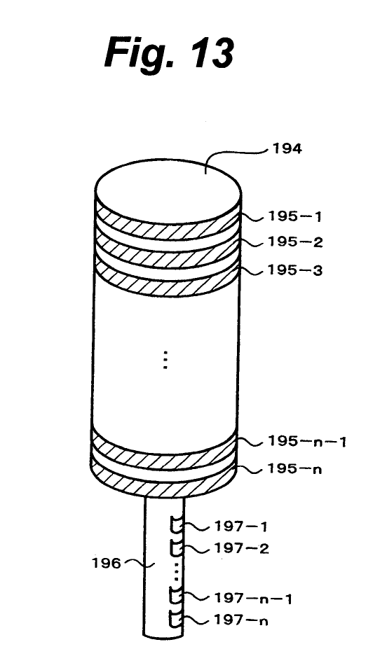

FIG. 13 shows the center shaft 194 in detail. As shown in FIG. 13, the surface of the center shaft 194 is formed from an insulating material and has formed thereon p-type contact layers 195-1 to 195-n axially separated from each other. Micro anodes 151-1 to 151-n are wound on the contact layers to be in contact with the latter. A connector 196 is provided at one end of the center shaft 194. The surface of the connector 196 is formed from an insulating material and has formed thereon electrodes 197-1 to 197-n separated axially from each other. The electrode 197-1 to 197-n are electrically connected to the p-type contact layers 195-1 to 195-n by internal wiring (not shown).

In case a solar battery system is formed from a plurality of these solar cells, the micro anodes 151 -k of the solar cells laid in a line are connected to each other while the micro anodes 152-k are connected to each other to output a voltage from the micro anode 151-k of the last one of the solar cells laid in each line. In this case, micro solar cells in the E_{gk} zones of the solar cells laid in one line are connected in parallel to each other.

The fifth embodiment is similarly advantageous to the third embodiment.

Next, a solar cell according to a sixth embodiment of the present invention will be explained.

The solar cell is shaped to have the general form of a thin, hexagonal plate. In other respects, this solar cell is similar to that according to the fifth embodiment.

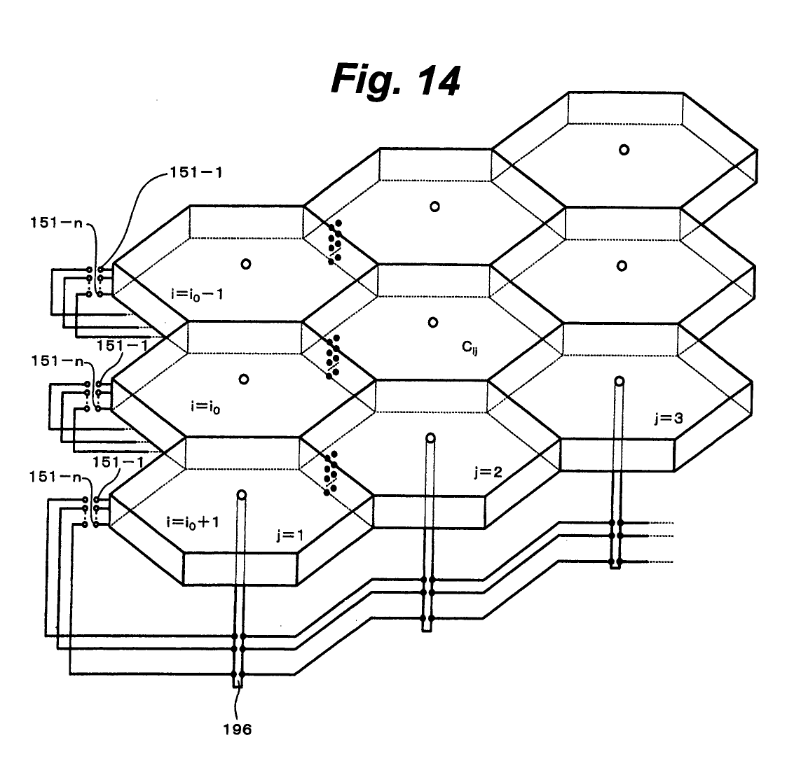

In case the hexagonal solar cells are bedded in a plane with no gap among them to build a solar battery system, the micro anodes 151-k of the solar cells laid in a line are connected to each other while the micro anodes 152-k are connected to each other to output a voltage from the micro anode 151-k of the last one of the solar cells laid in each line. In this case, micro solar cells in the E_{gk} zones of the solar cells laid in one line are connected in parallel to each other. In this embodiment, since the micro anode 151-k is exposed at the lateral side of the solar cell, just butt-joining the lateral sides of the solar cells to each other of the solar cells permits to provide electrical connection between the micro anodes 151-k. FIG. 14 shows this solar battery system.

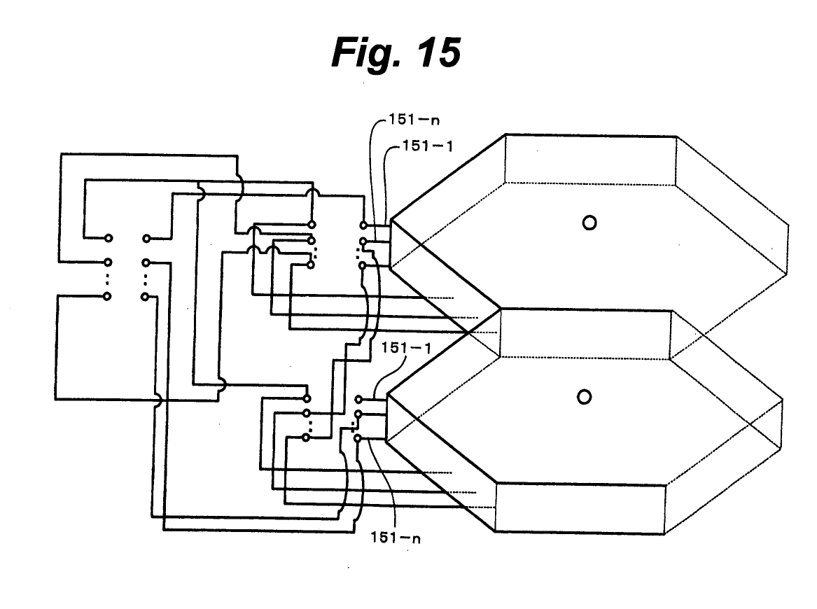

A voltage should preferably be outputted from the solar battery system as will be described below. A photo electromotive force developed between the micro anode 151-k and micro cathode 152-k of each of the micro solar cells included in the solar battery system is given by E_{gk}/e. Namely, the micro solar cells are different in photo electromotive force from each other. The photo electromotive force of each micro solar cell may be used as it is, but to make use of the most of the solar cells, the connection between the micro solar cells should preferably be adapted to provide a single output voltage. On this account, it is assumed taking E_{gn} as Δ that E_{gi}=E_{g1}−(i−1)Δ(i=1 to n). In this case, the micro solar cells in the E_{gk} zone of each of the solar cells laid in one line are connected in parallel to each other. In this case, when a j-th one of the solar cells in an i-th line is given by Cᵢⱼ, the micro solar cell in the E_{gk} zone (k≧2) of a first one C_{2i-1,1} of the solar cells laid in a (2i-1)th line and micro solar cell in the E_{g(n+2-k)} zone of a first one C_{2i,1} of the solar cells laid in a 2i-th line are connected in series to each other as shown in FIG. 15. The total photo electromotive force will be (E_{gk}+E_{g(n+2-k)})/e=E_{g1}/e. On the other hand, the photo electromotive force of the micro solar cell in the E_{g1} zone is E_{g1}/e. Therefore, these photo electromotive forces can be taken out from the same terminal to output a single output voltage from the solar battery system.

Next, there will be explained a clean unit and clean unit system, suitable for use in producing the functional devices according to the aforementioned first to sixth embodiments.

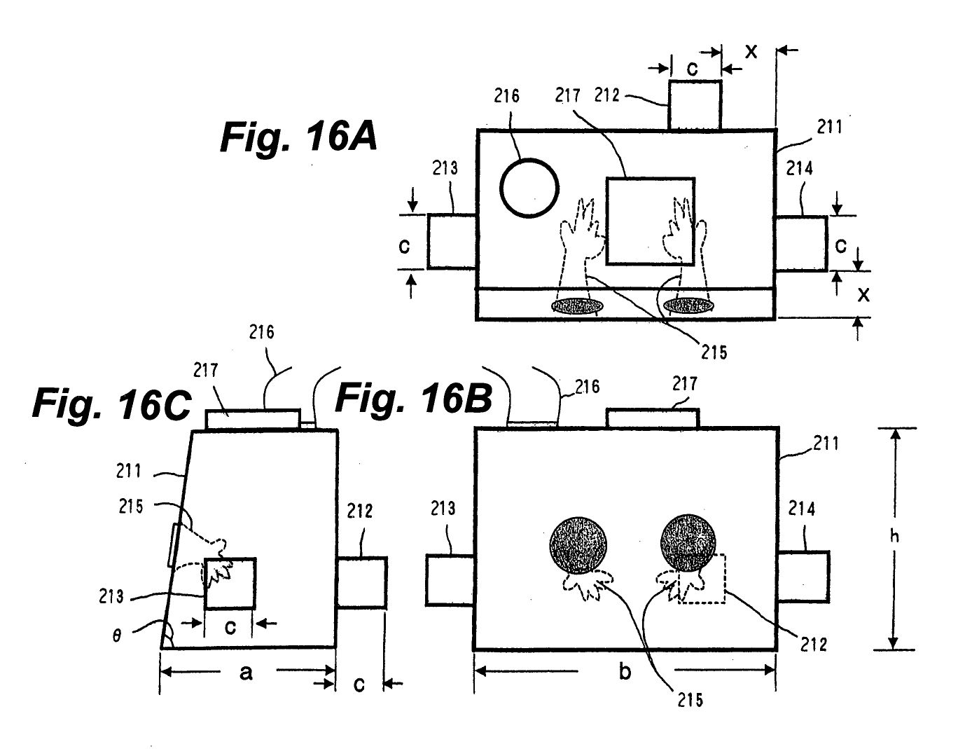

FIGS. 16A, 16B and 16C which are a plan view, front view and side elevation, respectively, schematically illustrate together a clean unit according to a seventh embodiment of the present invention. The clean unit is used mainly for a chemical process to which generation of a gas, use of an organic solvent and the like are incident, which however is not any limitative example of application.

As shown in FIGS. 16A, 16B and 16C, the clean unit includes a hexahedral box-shaped work chamber 211. The opposite lateral sides of this work chamber 211 are parallel to each other, and also the top and bottom are parallel to each other. The lateral sides, top, bottom, front and back are at right angles to each other, but the front is not parallel to the back and is inclined at an angle θ (70 to 80 deg., for example) to a direction in which the top gets close to the back. Transfer boxes 212, 213 and 214 that serve as an inter-clean unit connector and passageway are removably provided at the back and opposite lateral sides, respectively, of the work chamber 211. An opening (not shown in FIGS. 16A, 16B and 16C) is formed in the wall of the work chamber 211 on which the transfer boxes 212, 213 and 214 are provided. These transfer boxes 212, 213 and 214 can be used to connect one clean unit to another clean unit from the directions of the back and opposite lateral sides and carry workpieces between the clean units. In the front wall of the work chamber 211, there are formed two circular openings to which manipulation-use gloves 215 in pair are attached, respectively. The operator can make necessary work inside the work chamber with the hands being inserted in the manipulation-use gloves 215. On the top of the work chamber 211, there are installed an exhaust duct 216 and a passive dust filter 217 with no blower, which contribute to keeping the inside of the work chamber 211 as a clean environment nearly at Class 10 or 100, for example. The passive dust filter 217 may be, for example, a passive HEPA filter.

The front of the work chamber 211 is detachable so that with the front being detached, necessary equipment such as a process unit, observation apparatus, etc. can be introduced into the work chamber 211.

The size of the work chamber 211 is large enough to accommodate necessary process units etc. and for the operator to make necessary work in the work chamber 211 with the hands being inserted in the manipulation-use gloves 215. More specifically, the depth a of the work chamber 211 is 50 to 70 cm, width b is 70 to 90 cm and height h is 50 to 100 cm, for example, as shown in FIGS. 16A, 16B and 16C. Also, the work chamber 211 should preferably be formed from a transparent material such as an acrylic resin plate, for example, for the chamber inside to be visible from outside. For mechanical reinforcement, the acrylic resin plate may be fixed to a metal frame. The dimension c of the transfer boxes 212, 213 and 214 is, for example, 15 to 20 cm.

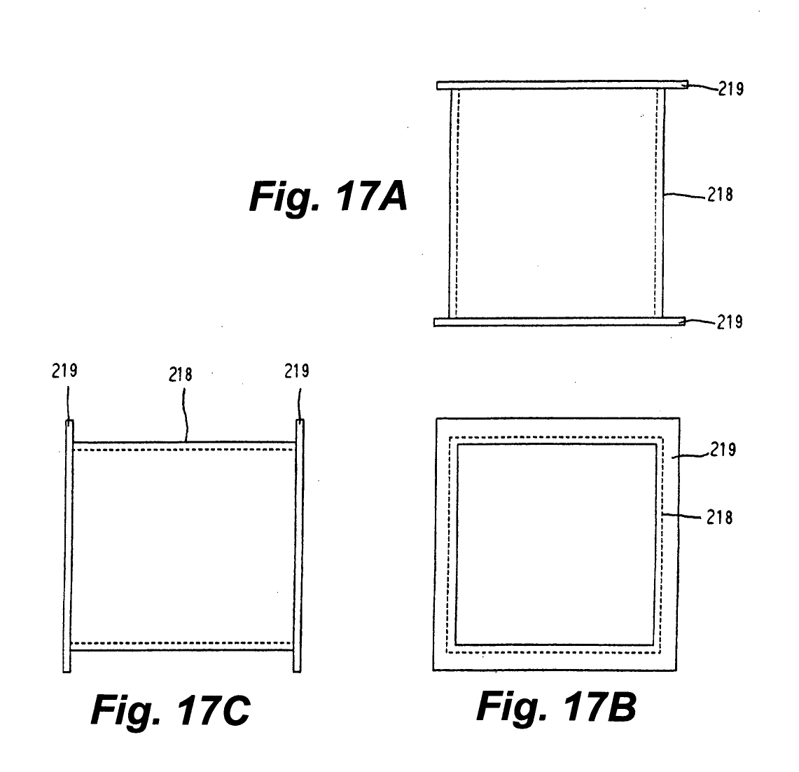

FIGS. 17A, 17B and 17C which are a plan view, front view and side elevation, respectively, schematically illustrate together an example construction of the transfer boxes 212, 213 and 214.

As shown in FIGS. 17A, 17B and 17C, each of the transfer boxes 212, 213 and 214 includes a body 218 having a rectangular section, and a picture frame-like flange 219 one size larger than the body 218 and formed at either end of the body 218. In this case, the inner wall of the flange 219 coincides with that of the body 218.

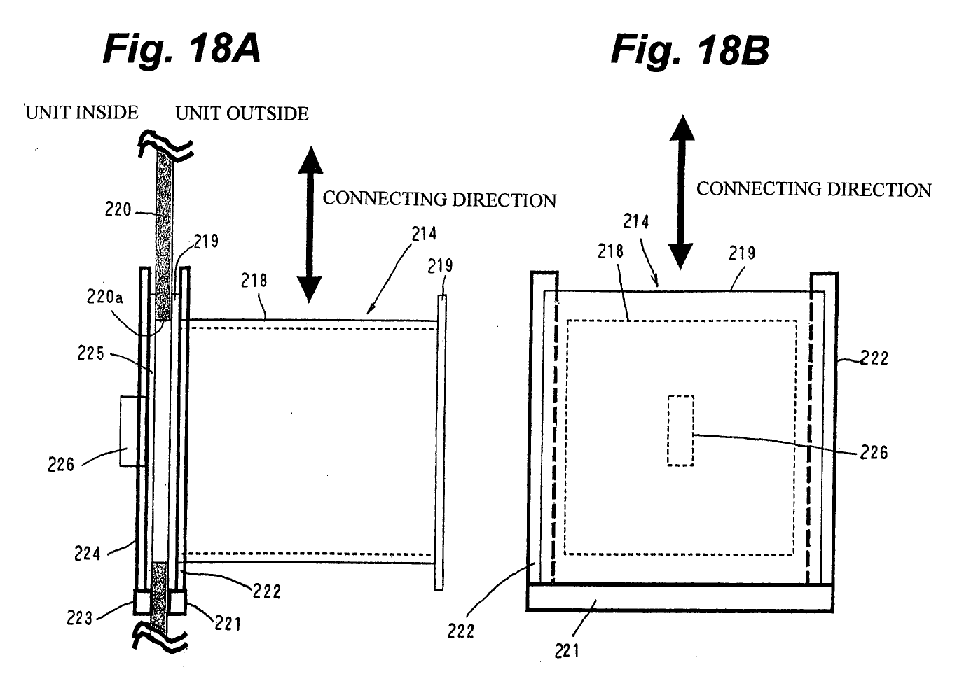

The work chamber 211 and transfer boxes 212, 213 and 214 are connected to each other as will be discussed below. Connection of the transfer box 214 to the right side of the work chamber 211 will be explained here by way of example, which is also true with the connection of the transfer boxes 212 and 213. As shown in FIGS. 18A and 18B, the work chamber 211 has a wall 220 to isolate the inside and outside of the work chamber 211 from each other, and the wall 220 has a rectangular opening 220a formed in a portion to which the transfer box 214 is to be fixed. Also, a horizontally extending stopper 221 is provided on the outer surface of the wall 220 and just below the opening 220a, and a pair of guide rails 222 extending vertically above the opposite ends of the stopper 221 are provided opposite, and in parallel, to each other. The clearance between these guide rails 222 and wall 220 is designed slightly larger than the thickness of the flange 219 of the transfer box 214. The flange 219 of the transfer box 214 is inserted at both lateral sides thereof into the clearance and slid along the guide rails 222 from above. When the lower end of the flange 219 touches the stopper 221, the flange 219, guide rails 222 and wall 220 are nearly appressed to each other. The transfer box 214 is completely installed.

A stopper 223 extending horizontally just below the opening 220a is provided also on the inner surface of the wall 220, and a pair of guide rails 224 extending vertically above the opposite ends of the stopper 223 are provided opposite, and in parallel, to each other. A rectangular sliding door 225 one size larger than the opening 220a is inserted at both lateral sides thereof into a clearance between the guide rails 224 and wall 220 and slid along the guide rails 224. When the lower end of the sliding door 225 touches the stopper 223, the sliding door 225, guide rails 224 and wall 220 is nearly appressed to each other and the inside and outside of the wall 220 are isolated from each other. The clearance between these guide rails 224 and wall 220 is designed a little larger than the thickness of the sliding door 225. The sliding door 225 has a handle 226. The operator can open or close the sliding door 225 by moving the latter vertically with the handle 226 in hand. By operating the sliding door 225 in this manner, the operator can control the communication/non-communication between the inside of the work chamber 211 and the transfer box 214.

The clean unit system can be expanded by attaching the transfer unit 214 to outside the opening 220a in the wall 220 with the inner sliding door 225 being closed, connecting the work chamber 211 of a next clean unit to the other end of the transfer box 214, and then opening the inner sliding door 225. That is, the space in the work chamber 211 can be kept clean, and this clean environment can be expanded in the horizontal direction and in the direction of depth.

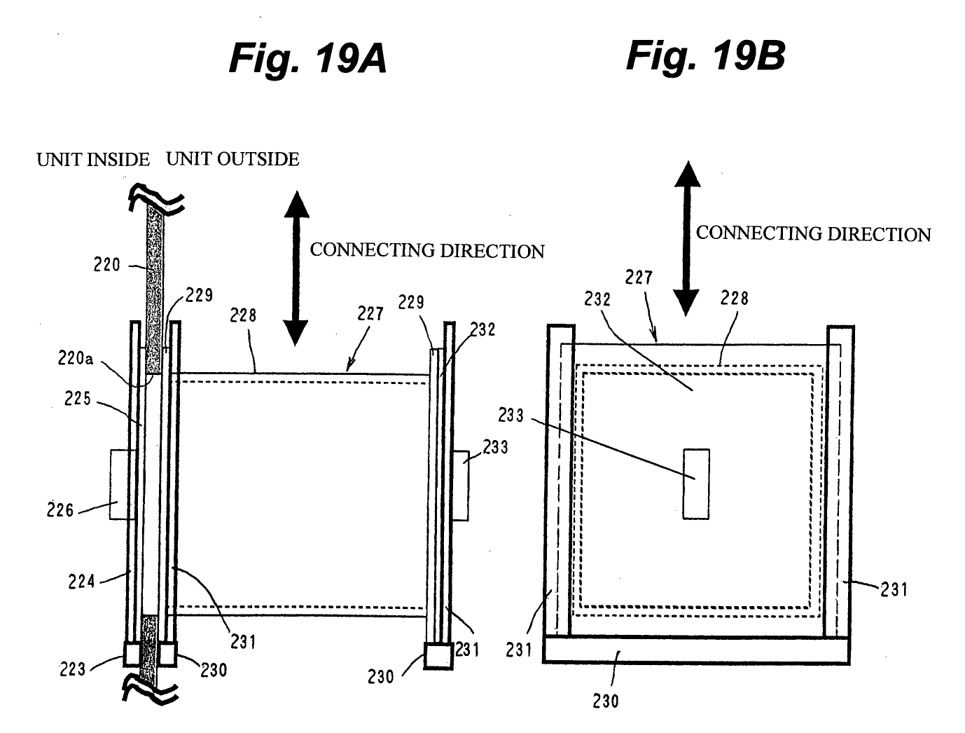

Next, there will be explained how a workpiece is put into the clean unit and taken out. As shown in FIGS. 19A and 19B, a next clean unit is not connected to the clean unit but a charge/discharge box 227 is installed to the work chamber 211 of the clean unit in order to put a workpiece into the clean unit and take it out. The charge/discharge box 227 is almost similar in construction to the transfer boxes 212, 213 and 214. That is, the charge/discharge box 227 includes a body 228 having a rectangular section, and a picture frame-like flange 229 one size larger than the body 228 and formed at either end of the body 228. A stopper 230 is fixed below one of the flanges 229, and a pair of guide rails 231 extending vertically above the opposite ends of the stopper 230 are provided opposite, and in parallel, to each other. The inner wall of the flange 229 coincides with that of the body 228. A rectangular shield plate 232 one size larger than the body 228 is inserted at opposite ends thereof into the clearance between the guide rails 231 and flange 229 and slid along the guide rails 231. When the lower end of the shield plate 232 touches the stopper 230, the shield plate 232, guide rails 231 and flange 229 are nearly appressed to each other and the inside and outside of the charge/discharge box 227 are isolated from each other. The clearance between these guide rails 231 and flange 229 is designed slightly larger than the thickness of the shield plate 232. The shield plate 232 has a handle 233. The operator can open or close the shield plate 232 by moving the latter vertically with the handle 233 in hand. By operating the shield plate 232 in this manner, the operator can control the communication/non-communication between the inside and outside of the charge/discharge box 227. Installation of the charge/discharge box 227 to the clean unit is the same as that of the transfer boxes 212, 213 and 214 to the clean box, and so will not be explained any more.

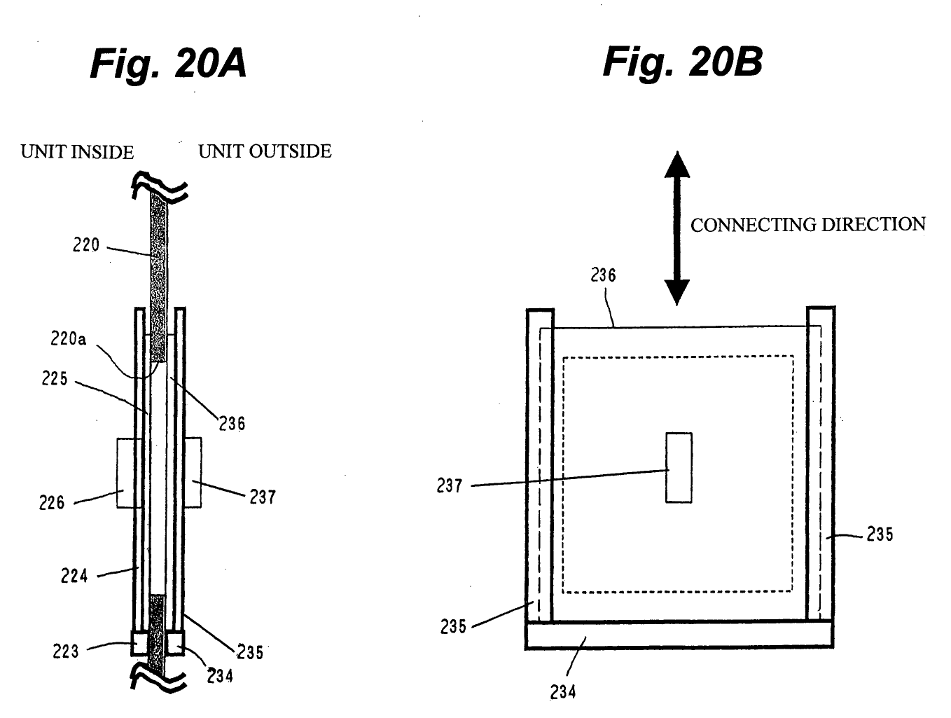

With regard to one of the connectors provided at three places on the clean unit, through which nothing is introduced or removed and which is not connected to any other clean unit, an opening/closing mechanism is also provided on the outer surface of the wall 220 as on the inner surface as shown in FIGS. 20A and 20B. More specifically, a stopper 234 and a pair of guide rails 235 are installed to the wall 220 of the work chamber 211. A rectangular shield plate 236 one size larger than the opening 220a is inserted at the opposite ends thereof into the clearance between the guide rails 235 and wall 220 and slide along the guide rails 235. When the lower end of the shield plate 236 touches the stopper 234, the shield plate 236, guide rails 235 and wall 220 are nearly appressed to each other to isolate the outside and inside of the wall 220 from each other. The clearance between the guide rails 235 and wall 220 is designed slightly larger than the thickness of the shield plate 236. The shield plate 236 has a handle 237. The operator can open or close the shield plate 236 by moving the latter vertically with the handle 237 in hand. By operating the shield plate 236 in this manner, the operator can control the communication/non-communication between the clean unit inside and outside. In this embodiment, the wall 220 has also a similar closing/operating mechanism provided on the inner surface thereof. That is, the wall 220 of the connector is doubly shielded. Thus, in case the clean unit is not connected to any other one and has no transfer box connected thereto, the inside of the work chamber 211 of the clean unit can efficiently be isolated from the atmosphere.

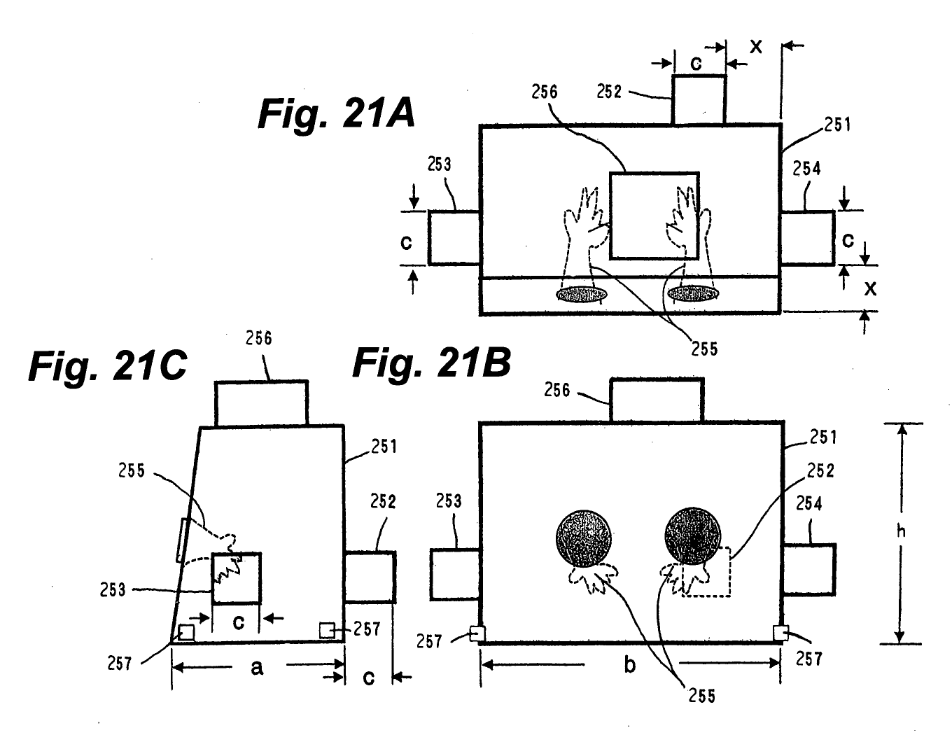

FIGS. 21A, 21B and 21C, which are a plan view, front view and side elevation, respectively, schematically illustrate together a clean unit according to an eighth embodiment of the present invention. This clean unit is to be used for performing non-chemical processes such as various kinds of measurement like surface observation, inspection, assembling, etc. which however are not any limitative examples of application.

As shown in FIGS. 21A, 21B and 21C, the clean unit has a work chamber 251 constructed similarly to the work chamber 211 of the clean unit shown in FIGS. 16A, 16B and 16C. As shown, transfer boxes 252, 253 and 254 are provided at the back and lateral sides, respectively, of the work chamber 251. The transfer boxes also serve as inter-clean unit connector and passageway. These transfer boxes 252, 253 and 254 can be used to connect another clean unit to this clean unit from three directions, namely, from the back and lateral sides, and a workpiece or the like can be carried through the transfer boxes 252, 253 and 254. Also, in the front surface of the work chamber 251, there are formed two circular openings to which manipulation-use gloves 255 in pair are attached. On the top of the work chamber 251, there is installed an active dust filter 256 with a blower, which contributes to keeping the inside of the work chamber 251 as a clean environment nearly at Class 10 or 100, for example. In this embodiment, no exhaust duct is provided but an exhaust ventilator 257 is provided instead at the lower corner of either lateral side of the work chamber 251. The exhaust ventilator 257 is to control the positive air pressure applied by the active dust filter 256 by exhausting air coming from the active dust filter 256 to outside the work chamber 251. The active dust filter 256 may be, for example, an active HEPA filter. It should be noted that in case this clean unit is used in place of a bio clean room, for example, an ion sterilization/clearing unit may be connected directly to the active dust filter 256.

In other respects, the clean unit as the eighth embodiment of the present invention is constructed similarly to that shown in FIG. 16.

In case the clean unit is not connected to any other clean unit, a shield plate or door may be attached to the connecting portion of the transfer boxes 252, 253 and 254 similarly to the clean unit shown in FIG. 16.

Next, there will be explained a clean unit system according to a ninth embodiment of the present invention.

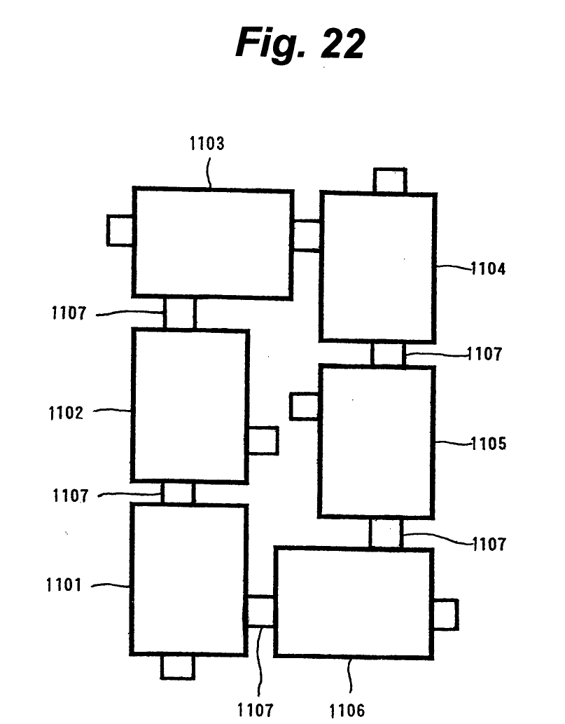

The clean unit system is schematically illustrated in FIG. 22. As shown in FIG. 22, the clean unit system includes clean units 1101 to 1106 of Type A or B, designed for three-directional connection. The clean units are connected in a loop to each other via a transfer box 1107. A transfer box 1107 no used for this connection is shielded by a shield plate.

The ninth embodiment is advantageous as follows. In general, one process is repeated often in a total series of processes. However, in case the same process is repeated in the conventional clean unit system in which clean units that can be connected only horizontally are connected to each other horizontally in a single line, a workpiece has to be returned back to an upstream clean unit at completion of each process. Therefore, the working efficiency is very low. In the ninth embodiment, however, since the clean units 1101 to 1006 are connectable in three directions, they can be connected to each other in an optimum loop for an intended process flow and a series of processes can be repeated a required number of times without having to carry the workpiece unnecessarily. Thus, the series of processes can be effected efficiently.

Next, there will be explained a clean unit system according to a tenth embodiment of the present invention.

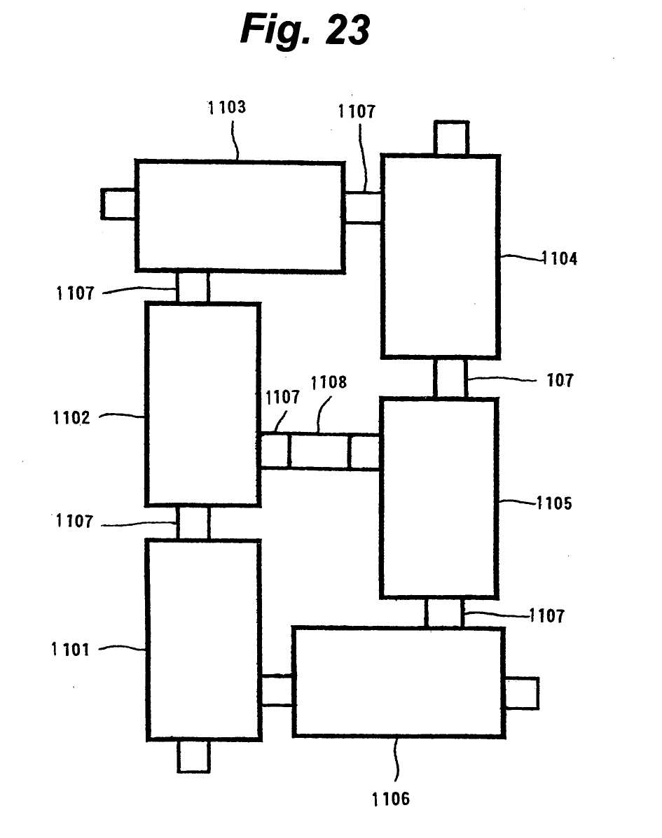

FIG. 23 shows the clean unit system as the tenth embodiment. As shown in FIG. 23, the clean unit system includes clean units 1101 to 1106 of Type A or B are connected in a loop to each other via a transfer box 1107, which is similar to the aforementioned ninth embodiment. In this embodiment, however, the clean units 1102 and 1105 are connected directly to each other via a transfer box 1107 and junction box 1108. In this case, the clean unit system may be so designed that the depth a of the work chamber, dimension c of the transfer box and distance x of the transfer box at the back from the right side in the drawing will be given by an expression x=(a−c)/2 as shown in FIGS. 16 or 21 to connect only the clean units 1101 to 1106 constructed according to the same specification to each other as shown in FIG. 23.

According to the tenth embodiment, the clean units 1101 to 1106 are connected to each other to form a loop and the clean units 1102 and 1105 are connected directly to each other via the transfer box 1107 and junction box 1108. So, the clean unit system as the tenth embodiment is advantageous similarly to the aforementioned ninth embodiment and further advantageous in that it can be branched or looped smaller for effecting a process more adaptationally. More specifically, a substrate can be processed being passed sequentially through the clean units 1101 to 1106. Also, after the substrate is processed first in the clean unit 1101 and then in the clean unit 1102, it can be passed to the clean unit 1105 in which it will further be processed, for example.

Next, there will be explained a clean unit according to an eleventh embodiment of the present invention.

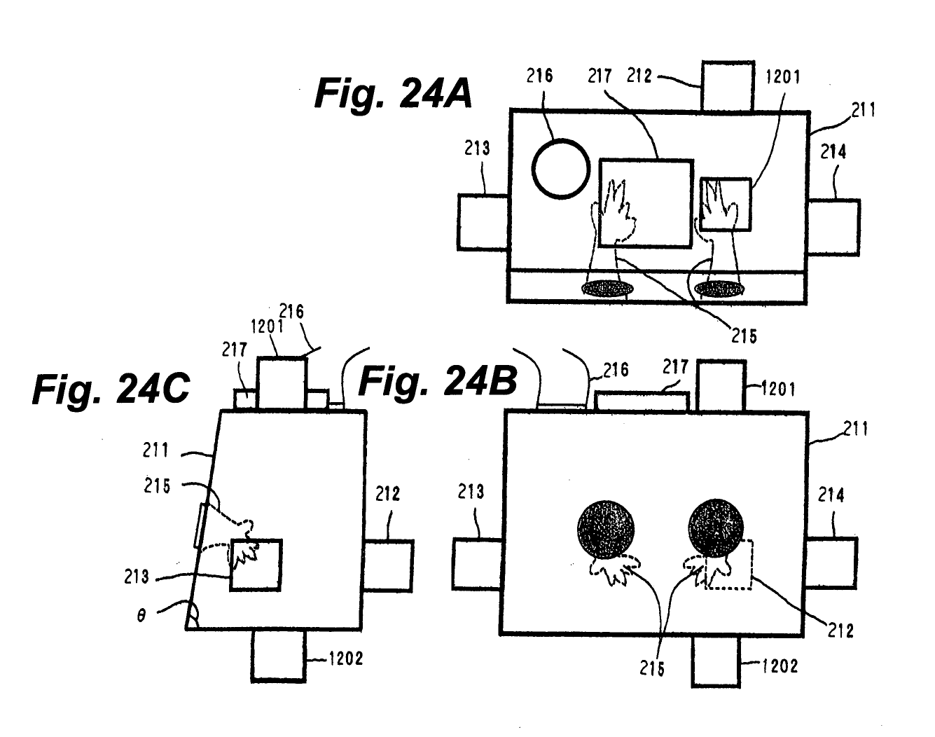

The clean unit as the eleventh embodiment is schematically illustrated in FIGS. 24A, 24B and 24C which are a plan view, front view and side elevation, respectively.

As shown in FIGS. 24A, 24B and 24C, the clean unit includes a hexahedral box-shaped work chamber 211. Transfer boxes 212, 213 and 214 are removably provided at the back and opposite lateral sides, respectively, of the work chamber 211, and transfer boxes 1201 and 1202 are removably provided at the top and bottom, respectively, of the work chamber 211. The transfer boxes 1201 and 1202 are constructed similarly to the transfer boxes 212, 213 and 214.

In other respects, this embodiment is similar to the seventh embodiment, and so will not be explained any more.

It should be noted that the clean unit according to the eleventh embodiment will be referred to as “Type C” hereunder.

Next, there will be explained a clean unit according to a twelfth embodiment of the present invention.

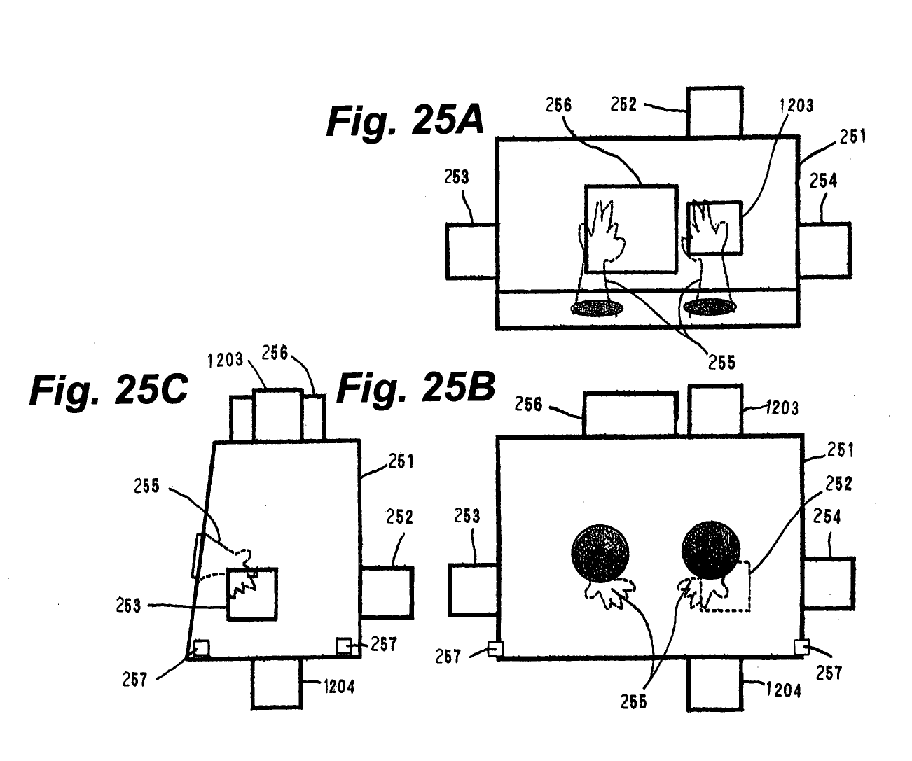

The clean unit as the twelfth embodiment is schematically illustrated in FIGS. 25A, 25B and 25C which are a plan view, front view and side elevation, respectively.

As shown in FIGS. 25A, 25B and 25C, the clean unit includes a hexahedral box-shaped work chamber 251. Transfer boxes 252, 253 and 254 are removably provided at the back and opposite lateral sides, respectively, of the work chamber 251, and transfer boxes 1203 and 1204 are removably provided at the top and bottom, respectively, of the work chamber 211. The transfer boxes 1203 and 1204 are constructed similarly to the transfer boxes 212, 213 and 214.

In other respects, this embodiment is similar to the eighth embodiment, and so will not be explained any more.

It should be noted that the clean unit according to the twelfth embodiment will be referred to as “Type D” hereunder.

Next, there will be explained a clean unit according to a thirteenth embodiment of the present invention.

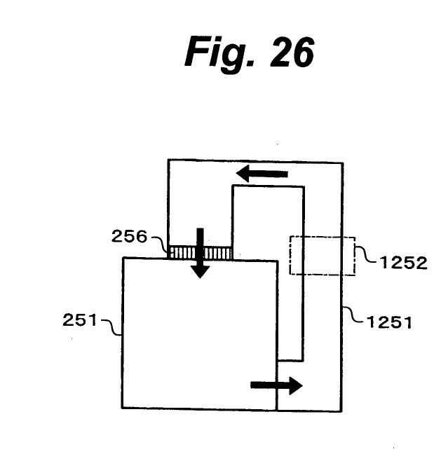

FIG. 26 is a front view of the clean unit as the thirteenth embodiment of the present invention.

As shown in FIG. 26, the clean unit has an exhaust ventilator (not shown) formed at the lower corner of the left lateral side of the work chamber 251. The exhaust ventilator is closed with a lid or the like (not shown) and an airtight tube 1251 is connected between the exhaust ventilator at the lower corner of the right lateral side and the inlet of an active dust filter 256 so that all the gas exhausted from the exhaust ventilator will enter the active dust filter 256 through the tube 1251. Thus, the gas is circulated through the active dust filter 256, work chamber 251, exhaust ventilator, tube 1251 and active dust filter 256 in this order, whereby the cleanliness inside the work chamber 251 can be improved considerably.

In case a chemical process is to be effected inside the work chamber 251, a chemical process-compatible active dust filter 256 is used and an adsorption tower 1252 or adsorbent is provided in the middle of the tube 1251, to thereby permit both removal of a harmful substance and maintenance of a clean environment in a closed system without having to connect the work chamber 251 to outside via any duct or the like.

Also, an adhesive tape is attached on all or part of the whole inner wall of the work chamber 251 to catch dust particles, whereby it is possible to further improve the cleanliness. In this case, the adhesive sheet may be a multilayered one. By peeling one of the adhesive-sheet layers at completion of each process to expose a clean sheet surface, the adhesion effect of the adhesive sheet to catch dust particles can always be maintained.

The work chamber 251 is not illustrated and explained in detail, but it is similar to the work chamber included in the eighth embodiment.

The clean unit as the thirteenth embodiment will be referred to as “Type E” hereunder.

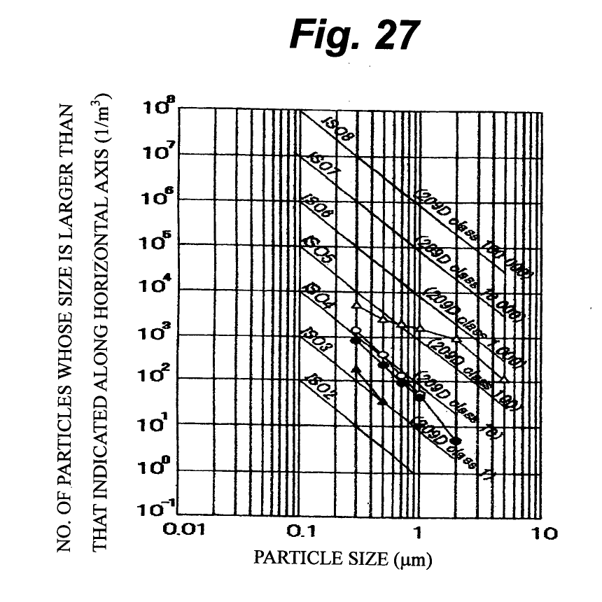

FIG. 27 shows the cleanliness inside the work chamber 251, measured with the Type-E clean unit being placed in an ordinary office environment and active dust filter 256 being in operation. In FIG. 27, the horizontal axis indicates the size (in μm) of particles and vertical axis indicates the number (pieces/m³) of particles larger than the particle size along the horizontal axis. It should be noted however that the work chamber 251 of the clean unit used in this measurement is cuboid and 80 cm wide, 60 cm deep and 80 cm high. The active dust filter 256 used was a HEPA unit GK-0757-01 (Model 25S), 0.3 μm, available from the AS ONE. Also, the measurement was made in 20 or 30 min after the active dust filter 256 was put into operation. As will be known from FIG. 27, the mean value (indicated with a small white circle in FIG. 27) of the cleanliness of the circulation-type clean unit is nearly at Class 10, and the maximum cleanliness value (indicated with a small black circle) is approximate to Class 1. The time taken for attaining the cleanliness was as short as 20 or 30 min after the active dust filter 256 was put into operation. The above shows that circulation of all the gas exhausted from the exhaust ventilator to the inlet of the active dust filter 256 through the tube 1251 is very effective for attaining a high cleanliness of the work chamber inside. FIG. 27 also shows cleanliness (indicated with a small white triangle) measured in a super-clean area of the clean room and that (indicated with a small black triangle) in an ordinary area.

In the foregoing, the present invention has been described in detail concerning certain preferred embodiments thereof as examples with reference to the accompanying drawings. However, it should be understood by those ordinarily skilled in the art that the present invention is not limited to the embodiments but can be modified in various manners, constructed alternatively or embodied in various other forms without departing from the scope and spirit thereof as set forth and defined in the appended claims.

For example, the numeric values, materials, shapes, disposition, etc. referred to in the explanation of the aforementioned embodiments are not any limitative ones but may be other ones when necessary. Two or more of the aforementioned embodiments may be combined together as appropriate.

Also, the concentric structure itself may be formed by a method other than having been described concerning the first to sixth embodiments. For example, different materials may be formed alternately by the vacuum evaporation on the lateral side of a shaft being rotated. Alternatively, different materials may be made to grow alternately on a columnar substrate by the MOCVD or the like method.

Also, other than the materials used in the aforementioned first to sixth embodiments may be used to form the concentric structure. The dielectric used may be an inorganic material such as oxide or an organic material such as polystyrene, polycarbonate or the like.

Further, the connection and integration of the bottom-up and top-down systems is not applied only to hardware in a narrow sense but is applicable to various aspects in which two systems are not compatible with each even if it is tried to combine them directly with each other.

The clean unit systems as the aforementioned seventh to thirteenth embodiments of the present invention are formed by disposing five types (Types A to E) of clean units equal in size to each other in a predetermined pattern and connecting them to each other. In the clean unit systems, however, the clean units of Types A to E may be different in size from each other. Otherwise, clean units equal in type to each other but different in size from each other may be used to form the clean unit system. Further, three or more types of clean units may be used together to build the clean unit system.

In the clean unit systems as the ninth and tenth embodiments, a three-dimensional connection may partially be adopted based on the freedom of vertical connection between the clean units. Also, the shield plate of the transfer box may be of a type using a gasket. Some of the clean units and transfer boxes may be constructed for resistance against a pressure or vacuum. In this case, the transfer box should desirably be designed to have an increased airtightness and have a pressure device or local exhaust unit provided therein. Also, the transfer box may not necessarily be linear but may be dog-legged, for example. Also, designing the transfer box to be connectable in three directions permits to dispose the clean units in a T pattern. Further, after the clean units are connected to each other, the sliding doors of all the transfer boxes may be opened and an automatic conveyor such as an elbowed conveyor be provided through the clean unit system.

As having been described in the foregoing, the present invention can provide a novel, higher-efficiency solar cell and photoelectric conversion device.

More generally, the present invention can provide a high-performance functional device making the most of the advantages of a bottom-up system represented by a living organism and a top-down system represented by a silicon LSI.

Also, by creating bulk-size systems discreted in a nano scale and combining, for example, an LSI system formed on a silicon substrate and an autonomous system disposed in the vicinity of the LSI system, it is possible to provide a platform that connects a bottom-up and top-down systems to each other.

According to the present invention, the clean units (with the connectors) may be connected to each other in one of various patterns of disposition and with a large freedom of connection to implement a highly functional clean unit system permitting to easily provide a clean environment and advanced bleeding environment without use of any large-scale clean room or plant factory requiring a large capital investment and on which a large fixed asset tax is imposed, maximize the total performance in all the respects of investment, working efficiency and efficiency of room space utilization by giving a solution to the low efficiency of space utilization of the conventional clean units that can be connected only linearly to each other to, and carry out processes correspondingly to a total series of on-target process flows, easily, with a high flexibility and at a lower cost. Also, since a clean unit system may be built from a minimum number of clean units of a minimum number of types used in a total range from upstream to downstream of a process, so the process efficiency can be maximized. Also, the present invention easily implements an advanced process environment without any degradation of the working efficiency.

Further, in producing a nano-technology device or carrying out a biotechnology process, at least part of a large box, namely, a clean room, ranging from the inlet to outlet, may be replaced with a plurality of super-clean clean units disposed in a loop or in a vertical zigzag line to improve the efficiency of space or area utilization.

Also, clean units of more than one type may be used to carry out a chemical process, non-chemical process, bio process and the like in one high-function clean unit system.

Also, the present invention permits to create a next-generation key structure such as a micro structure or make plant transformation by a less-demanding method higher in cost performance.

Also, the present invention permits plant breeding in a desired local environment as well as early-yield cultivation and cultivation of enriched vegetables and herbs.

Also, the present invention permits to build a consistent process line at a lower cost irrespectively of the performance of a room in which devices are to be disposed. Thus, the present invention permits a venture business to enter the field of manufacture with a smaller capital investment. Also, the present invention permits a small or middle venture business having only a small fixed asset to provide an advanced nano-technology product and thus a nano-technology hardware industry to rise into power as a new industry like the IT software prosperity.

Also, the present invention permits to produce a novel and improved nano-technology device by a less-demanding method higher in cost performance (which is not any method of producing a high-technology device as an extension of the conventional one).

Also, according to the present invention, the clean unit system may be formed from clean units connected to each other and of which the cleanliness and degree of harmlessness are set for each of process elements to consistently perform element processes such as pre-processing, resist coating, baking, exposure, development, post-baking, etching, growth of thin film, metalization, surface observation, assembling, etc. in a highly clean environment.

Also, according to the present invention, each process may be taken as an element, each of the clean units or functional units may be given the function of the element process and the clean units or functional units be connected to each other corresponding to an intended purpose, to thereby form a total system which provides a high-efficiency nano-technology platform or biotechnology platform. Also, nano-technology process units and biotechnology process units may be mixed together or connected to each other to provide a nano-technology/biotechnology platform. In addition, plant factory units may be connected to each other.

Also, a process flow can be executed with a minimum number of clean units, maximum efficiency and without any clean room by including subroutines and a concept such as branching in the process flow as in programming. Also, being likened to a computer program, a series of all or main ones of the processes from charging of a workpiece to output of a product lot can be performed in a full automatic manner.

Further, the present invention can provide an environment that can implement the nano-technology and biotechnology ubiquitously.

The invention is claimed as follows:

1. A clean unit in which an active dust filter is used to keep a work chamber as a clean environment, wherein the cleanliness of the work chamber depends upon 1/γ where γ is the dust collection efficiency of the dust filter.

2. The clean unit of claim 1, wherein Sσ/γV is minimum (V is the gas flow rate of the dust filter, S is the inner area of the work chamber and σ is the dust particle desorption rate per unit area and per unit time).

3. The clean unit of claim 1, wherein the dust filter is a HEPA or ULPA filter.

4. The clean unit of claim 1, wherein all gas flowing out of the work chamber enters the inlet of the active dust filter.

5. The clean unit of claim 1, wherein an airtight tube connected directly to the work chamber is connected to the inlet of the dust filter to circulate gas and assure the airtightness of the work chamber.

6. The clean unit of claim 5, wherein an adsorbent source or adsorption tower is connected to the tube.

7. The clean unit of claim 1, wherein an adhesive sheet is attached on at least a part of the inner wall of the work chamber.

8. The clean unit of claim 1, wherein the inner wall surface of the work chamber has not any Fourier component of a surface irregularity on the order of the size of the dust particles to be removed from the work chamber.
